(19) United States
(12) Patent Application Publication
(10) Pub. No.: US 2026/0114261 A1
(43) Pub. Date: Apr. 23, 2026

(54) MEMORY DEVICES AND METHODS OF FABRICATING THE SAME

(71) Applicant: Taiwan Semiconductor Manufacturing Company, Ltd., Hsinchu (TW)

(72) Inventors: Chia-En Huang, Hsinchu (TW); Tzu-Yu Chen, New Taipei City (TW)

(73) Assignee: Taiwan Semiconductor Manufacturing Company, Ltd., Hsinchu (TW)

(21) Appl. No.: 18/918,696

(22) Filed: Oct. 17, 2024

(51) Int. Cl. H01L 23/528; H01L 23/48; H01L 23/522; H01L 29/06; H01L 29/417; H01L 29/423; H01L 29/51; H01L 29/66; H01L 29/775; H01L 29/786

(52) U.S. Cl. CPC H10W 20/435; H10D 30/014; H10D 30/43; H10D 30/6729; H10D 30/6735; H10D 30/6757; H10D 62/121; H10D 64/689; H10W 20/20; H10W 20/42

(57) ABSTRACT

A semiconductor device includes a first transistor disposed on a first side of a substrate. The semiconductor device includes first interconnect structures disposed over the first transistor on the first side. The semiconductor device includes a memory element disposed on a second side of the substrate opposite to the first side, where the memory element includes at least a capacitor. The semiconductor device includes a via structure extending through the substrate and electrically coupling the memory element to the first interconnect structures.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 7, 8, 9, 10, and 12 each illustrate a cross-sectional view of an example semiconductor device, in portion or in entirety, according to some embodiments of the present disclosure.

FIGS. 2, 3, 4, 5, 6, and 11 each illustrate a portion of one or more of the example semiconductor device illustrated in one or more of FIGS. 1, 7, 8, 9, 10, and 12, according to some embodiments of the present disclosure.

FIG. 13 illustrates a flow chart of an example method for fabricating an example semiconductor device, according to some embodiments of the present disclosure.

FIGS. 14, 24, and 25 each illustrate a flow chart of an example method for implementing one or more steps of the method of the flow chart of FIG. 13, according to some embodiments of the present disclosure.

FIG. 15 illustrates a three-dimensional perspective view of an example semiconductor device, in portion or in entirety, according to some embodiments of the present disclosure.

FIGS. 16, 17, 18, 19, 20, 21, 22, 23, 26, 27, 28A, 29A, 30A, 31, 32, and 33 each illustrate a cross-sectional view of the example semiconductor device of FIG. 15, in portion or in entirety, during various fabrication stages of the methods illustrated in the flow charts of FIGS. 13, 14, 24, and/or 25, according to some embodiments of the present disclosure.

FIGS. 28B, 29B, and 30B each illustrate a top view of the example semiconductor device of FIGS. 28A, 29A, and 30A, respectively, according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In contemporary semiconductor device fabrication processes, a large number of semiconductor devices, such as field effect transistors are fabricated on a single wafer. Non-planar transistor device architectures, such as fin-based transistors (typically referred to as “FinFETs”), can provide increased device density and increased performance over planar transistors. Some advanced non-planar transistor device architectures such as nanostructure transistors (e.g., nanosheet transistors, nanowire transistors, gate-all-around (GAA) transistors, multi bridge channel (MBC) transistors, etc.) can further increase device performance. The nanostructure transistor, in general, includes a gate structure that wraps around the perimeter of one or more nanostructures for improved control of channel current flow.

Such a nanostructure transistor generally allows interconnect structures to be more efficiently formed on both a frontside and a backside of the device, given the nature of how the nanostructure transistor is formed. In comparison, a planar transistor device architecture typically requires corresponding interconnect structures to be only formed over a top surface of the transistors (e.g., typically referred to as a part of a back-end-of-line (BEOL) routing). In existing technologies, various memory cells in a memory device may be integrated with such nanostructure transistors in the BEOL routing on the frontside of the memory device, with the transistors functioning as logic devices (e.g., drivers) of the memory device. In this regard, the various components of the memory device are formed within the same space (e.g., the BEOL routing), rendering it increasingly challenging to improve device density on the frontside.

The present disclosure provides various embodiments of a semiconductor device (e.g., a memory device) that includes a logic portion and a memory portion. In various embodiments, the logic portion, which includes a number of transistors functioning as logic devices, may be formed on a frontside (e.g., a first side) of a substrate; and the memory portion, which includes a number of memory cells, may be formed, at least in part, on a backside (e.g., a second side) of the substrate opposite to the frontside. Such configuration allows for more compact design for the disclosed semiconductor device. As a result, dimensions (e.g., a gate pitch) of the transistors in the logic portion can be further reduced, and the backside can be utilized to provide more space for forming additional components and/or devices that can be coupled to the frontside components and/or devices through various interconnect structures, such as through-substrate-via structures (TSVs). Additionally, the backside integration technologies disclosed can also provide additional routing options for the memory device. In turn, the memory device, as disclosed herein, can have a greater density of memory cells integrated therein within the same area.

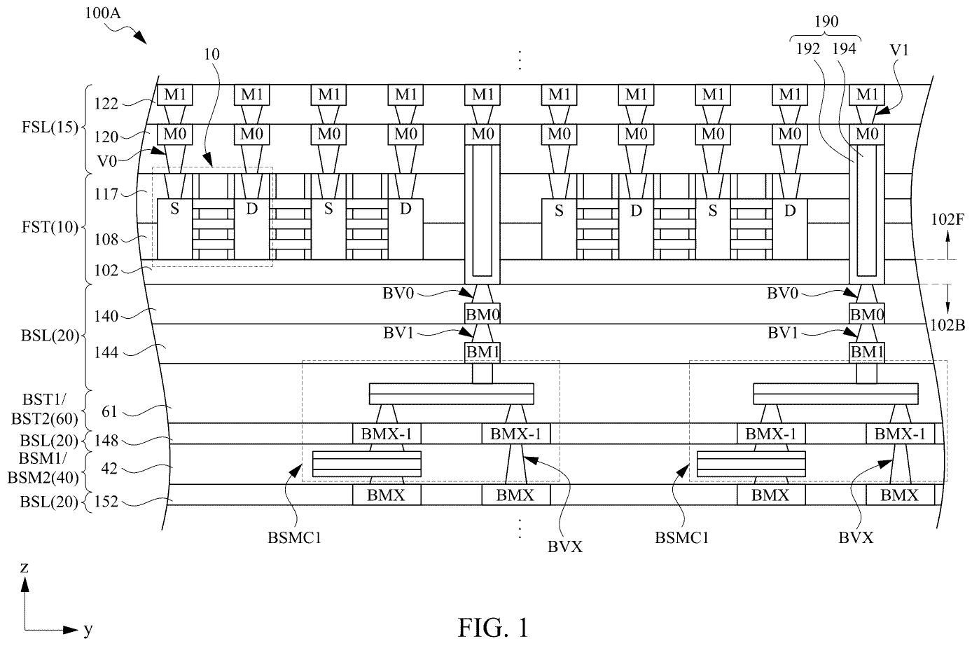

FIG. 1 illustrates a cross-sectional view of an example semiconductor device 100A (alternatively referred to as a memory device), in portion or in entirety, according to some embodiments of the present disclosure. The semiconductor device 100A (or “device” for short) includes a substrate 102 having a frontside 102F (e.g., a first side) and a backside 102B (e.g., a second side) opposite to the frontside 102F. The device 100A includes a plurality of frontside transistors 10 (FSTs) and a plurality of frontside interconnect structures 15 (FSLs) disposed over (or on) the frontside 102F, where at least some portions of the FSLs 15 are electrically coupled to the FSTs 10. In the depicted embodiments, the FSLs 15 are disposed over (or above) the FSTs 10 along a vertical direction (e.g., the Z axis). In the depicted embodiment of FIG. 1, the FSTs 10 are configured as logic devices (e.g., drivers) that constitute the logical portion of the device 100A.

As used herein, the term “electrically coupled” may be used interchangeably with “physically coupled” or “operatively coupled.” The term “electrically coupled” may be used to describe any direct electrical connection between two components without any intervening components; alternatively, it may be used to describe any indirect electrical connection between two components with one or more intervening components therebetween.

As depicted in FIG. 1, a bottom (e.g., at a location proximal to the substrate 102) portion of the FST 10 is embedded (or encapsulated) in isolation structures 108 disposed over the substrate 102, and a top (e.g., at a location distal to the substrate 102) portion of the FST 10 is embedded in an interlayer dielectric (ILD) layer 117. The isolation structures 108 are configured to electrically isolate neighboring active structures (e.g., adjacent fin structures or adjacent stacks of nanostructure channel layers) from one another. The isolation structures 108 may include an oxide, such as silicon oxide, a nitride, a low-k dielectric material (e.g., a dielectric material having a dielectric constant less than that of silicon oxide, which is about 3.9), such as phosphosilicate glass (PSG), borosilicate glass (BSG), boron-doped phosphosilicate glass (BPSG), undoped silicate glass (USG), other suitable materials, or combinations thereof.

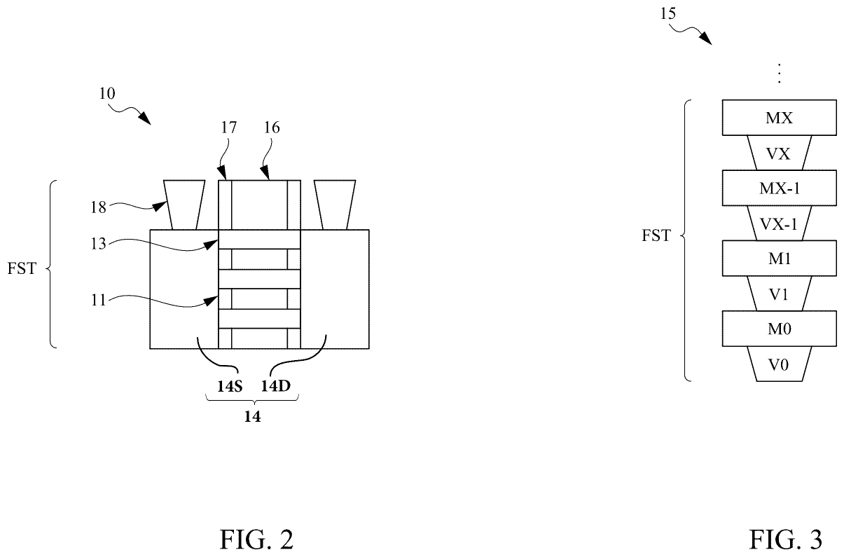

The device 100A, as depicted in FIG. 1, may include a plurality of FSTs 10 arranged along a first lateral direction (e.g., the Y axis) in a fin structure. Referring to FIG. 2, each FST 10 includes a plurality of nanostructures 13 stacked along the vertical direction. The nanostructures 13 include a semiconductor material and are configured as a plurality of channels of the FST 10. In the present disclosure, the nanostructures 13 may be alternatively referred to as semiconductor layers 13 or channel layers 13. Though the nanostructures 13 are depicted as nanosheets in the present embodiments, the nanostructures 13 may be alternatively formed as other types of structures, such as nanorods or nanowires, for example.

The nanostructures 13 may include any suitable semiconductor material, such as silicon (Si), silicon germanium (SiGe), a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GaInP, and/or GaInAsP, any other suitable materials, or combinations thereof. In some embodiments, the nanostructures 13 are substantially free of any dopant (e.g., p-type dopant o n-type dopant). In some embodiments, the nanostructures 13 are intentionally doped. For example, the nanostructures 13 may be doped with a p-type dopant such as boron (B), aluminum (Al), indium (In), gallium (Ga), other p-type dopants, or combinations thereof. Alternatively, the nanostructures 13 may be doped with an n-type dopant such as phosphorus (P), arsenic (As), antimony (Sb), other n-type dopants, or combinations thereof.

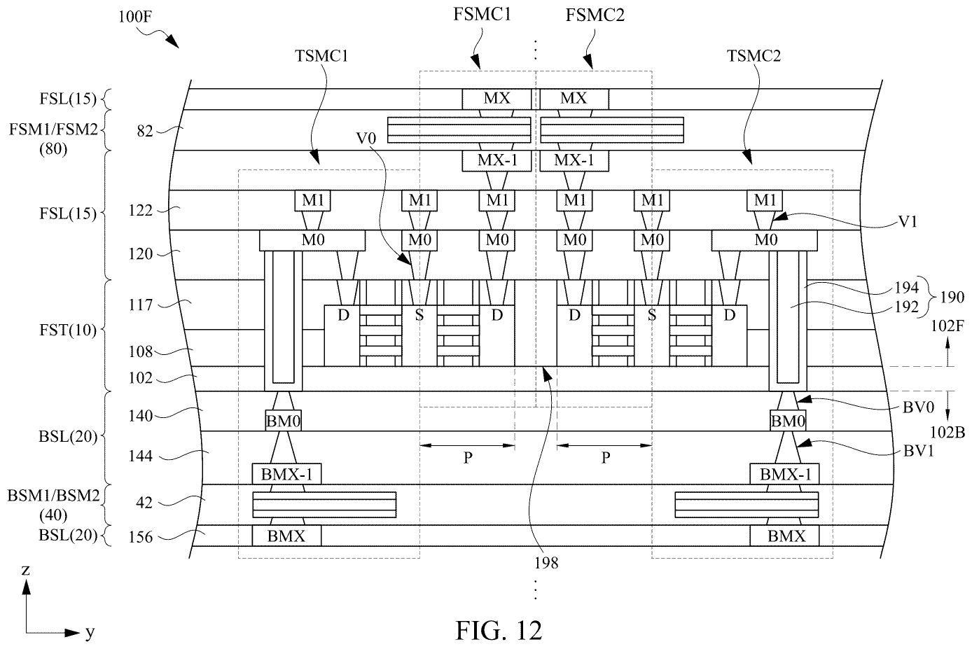

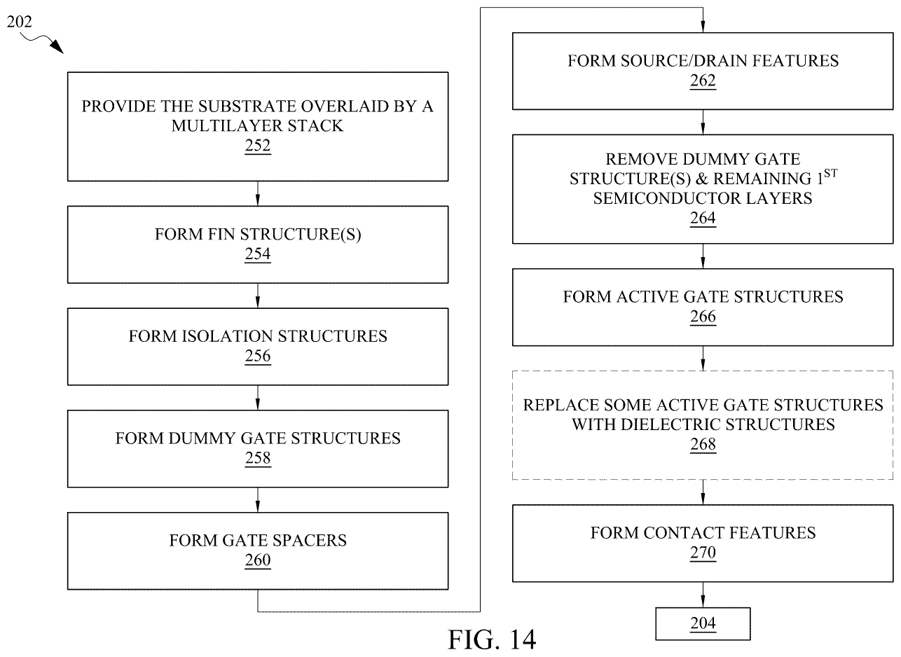

Referring to FIG. 2, the FST 10 includes a source feature 14S and a drain feature 14D (collectively referred to as source/drain features 14 hereafter) each electrically coupled to an end of the nanostructures 13. As such, the source/drain features 14 each extend vertically over the entire stack of the nanostructures 13. For embodiments in which the FST 10 is configured as an n-type device, the source/drain features 14 may include Si doped with an n-type dopant described herein. For embodiments in which the FST 10 is configured as a p-type device, the source/drain feature 14 may include SiGe doped with a p-type dopant described herein. In some embodiments, each source feature 14S is a common source feature shared by two adjacent FSTs 10 disposed along the first lateral direction (see FIGS. 10 and 12).

Still referring to FIG. 2, the FST 10 includes an active gate structure 16 having at least a bottom (or lower) portion that wraps around each nanostructure 13. In this regard, the bottom portion of the active gate structure 16 is interleaved with the stack of the nanostructures 13.

Furthermore, the active gate structure 16 includes a top (or upper) portion disposed over a topmost nanostructure 13 in the stack. In some embodiments, the active gate structure 16 includes a gate dielectric layer and a gate metal over the gate dielectric layer (not depicted separately in FIG. 2).

The gate dielectric layer may include any suitable dielectric material, such as a high-k dielectric material (e.g., a dielectric material having a dielectric constant greater than that of silicon oxide, which is about 3.9). Example high-k dielectric materials include a metal oxide or a metal silicate of Hf, Al, Zr, La, Mg, Ba, Ti, Pb, any other suitable materials, or combinations thereof. Additionally or alternatively, the gate dielectric layer may include silicon oxide, silicon oxynitride, other suitable dielectric materials, or combinations thereof. The gate dielectric layer may include a stack of multiple different dielectric materials.

The gate metal may include a stack of multiple metal materials. For example, the gate metal may include at least a work function layer (not depicted separately) and a conductive fill layer (not depicted separately) disposed over the work function layer. The work function layer may include a p-type work function layer, an n-type work function layer, multi-layers thereof, any other suitable materials, or combinations thereof. The work function layer may also be referred to as a work function metal. Example work function metals may include TiN, TaN, Ru, Mo, Al, WN, ZrSi2, MoSi2, TaSi2, NiSi2, Ti, Ag, TaAl, TaAIC, TiAIN, TaC, TaCN, TaSiN, Mn, Zr, other suitable materials, or combinations thereof. The conductive fill layer may include any suitable conductive material, such as polycrystalline silicon (polysilicon), tungsten (W), copper (Cu), cobalt (Co), ruthenium (Ru), aluminum (Al), titanium (Ti), tantalum (Ta), gold (Au), silver (Ag), platinum (Pt), other suitable conductive materials, or combinations (or alloys) thereof. The active gate structure 16 may further include additional layers, such as glue layers (or adhesive layers), capping layers, barrier layers, other suitable layers, or combinations thereof.

Referring to FIG. 2, the FST 10 includes inner spacers 11 interposed between a portion of the active gate structure 16 and the source/drain features 14 along the first lateral direction. The FST 10 further includes gate spacers 17 each extending along a sidewall of the top portion of the active gate structure 16. The inner spacers 11 and the gate spacers 17 may each include any dielectric material, such as silicon oxide, silicon nitride, silicon oxycarbonitride, other suitable materials, combinations thereof. The inner spacers 11 and the gate spacers 17 may each include multiple layers of different dielectric materials. The inner spacers 11 and the gate spacers 17 may include the same or different dielectric material(s).

Still referring to FIG. 2, the FST 10 further includes various contact features electrically coupled to at least one of the source feature 14S, the drain feature 14D, and the active gate structure 16 (e.g., the conductive fill layer thereof). In the depicted embodiment, the FST 10 includes a source/drain contact 18 electrically coupled to at least one of the source/drain features 14. The source/drain contact 18 may include a conductive fill layer (not depicted separately) having a conductive material such as W, Cu, Co, Ru, Al, Ti, Ta, Au, Ag, Pt, other suitable conductive materials, or combinations (or alloys) thereof. The source/drain contact 18 may include a barrier layer (not depicted) separating the conductive fill layer from the surrounding components. The barrier layer may include Ti, Ta, TiN, TaN, other suitable materials, or combinations thereof. The source/drain contact 18 may further include a metal silicide layer (not depicted) disposed between the conductive fill layer and the underlying source/drain features 14. The metal silicide layer may include, for example, NiSi.

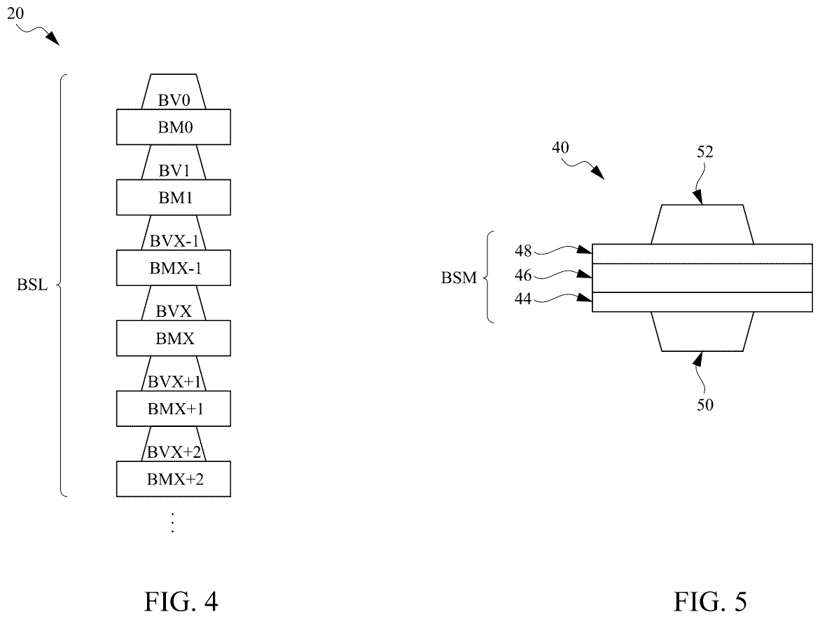

Referring to FIGS. 1 and 3 collectively, the FSLs 15 include multiple dielectric layers (e.g., intermetal dielectric (IMD) layers) in which vertical conductive features (alternatively referred to as interconnect conductive features), such as vias, and horizontal conductive features, such as metal (or conductive) lines, are embedded. For example, the FSLs 15 may include IMD layers 120 and 122 vertically stacked over the ILD layer 117. The FSLs 15 may include a via V0 and a metal line M0 embedded in the IMD layer 120, where the via V0 interconnects a portion of the FST 10 to a metal line M0. The FSLs 15 may further include a via V1 and a metal line M1 embedded in the IMD layer 122, where the via V1 interconnects the metal line M0 to the metal line M1. In some embodiments, each of the IMD layers 120, 122 includes multiple dielectric layers each encapsulating a via (e.g., the vias V0, V1, etc.) or a metal line (e.g., the metal lines M0, M1, etc.).

Each frontside IMD layer and the corresponding conductive features embedded therein may be collectively referred to as a frontside metallization layer. For example, the IMD layer 120, the via V0, and the metal line M0 may be collectively referred to as the zeroth frontside metallization layer; the IMD layer 122, the via V1, the metal line M1 may be collectively referred to as the first frontside metallization layer; and so on. Referring to FIG. 3, additional frontside metallization layers including conductive features such as VX−1, MX−1, VX, and MX, etc., may be formed over the IMD layer 122 on the frontside 102F.

The ILD/IMD layers 117, 120, 122 may each include an oxide, such as silicon oxide, a low-k dielectric material, such as phosphosilicate glass (PSG), borosilicate glass (BSG), boron-doped phosphosilicate glass (BPSG), undoped silicate glass (USG), other suitable dielectric materials, or combinations thereof. In some embodiments, the ILD/IMD layers 117, 120, 122 include the same composition as the isolation structures 108. The various conductive features V0, V1, M0, M1 embedded in the corresponding ILD/IMD layers 117, 120, 122 each include a conductive fill layer (not depicted separately) having a conductive material such as W, Cu, Co, Ru, Al, Ti, Ta, Au, Ag, Pt, other suitable conductive materials, or combinations (or alloys) thereof. In some embodiments, the conductive features each include a barrier layer (not depicted) separating the conductive fill layer from the surrounding ILD/IMD layers. The barrier layer may include Ti, Ta, TiN, TaN, other suitable materials, or combinations thereof.

Referring to FIG. 1, the device 100A further includes a plurality of backside interconnect structures 20 (BSLs) and at least one backside memory element 40 (BSM) over (or on) the backside 102B. Each BSM 40 is embedded within and electrically coupled to portions of the BSLs 20 along the vertical direction. For example, a top (e.g., at a location proximal to the substrate 102) portion of the BSM 40 is electrically coupled to a first portion of the BSLs 20 and a bottom (e.g., at a location distal to the substrate 102) portion of the BSM 40 is electrically coupled to a second portion of the BSLs 20, where the second portion is below the first portion. In some embodiments, the device 100A optionally includes a backside transistor 60 (BST) embedded within the BSLs 20 and electrically coupled to one of the BSM 40 in series. As will be described in detail below, the BST 60 may differ from the FST 10 in structure and/or function.

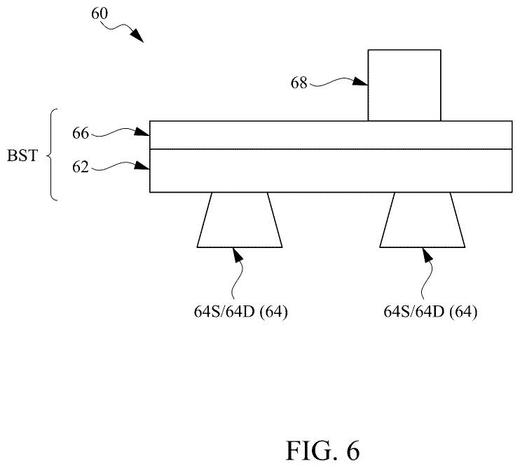

Referring to FIGS. 1 and 4 collectively, structure of the BSLs 20 may be similar to that of the FSLs 15. For example, the BSLs 20 include multiple IMD layers 140, 144, 148, and 152 stacked over (or on) the backside 102B. In this regard, the IMD layers 140-152 are disposed below the FSTs 10 and opposite to the FSLs 15 along the vertical direction. The BSLs 20 may include a via BV0 and a metal line BM0 embedded in the IMD layer 140, where the via BV0 interconnects a portion of the frontside components (e.g., a through-substrate-via structure (TSV) 190) to a metal line BM0. The BSLs 20 may include a via BV1 and a metal line BM1 embedded in the IMD layer 144, where the via BV1 interconnects the metal line BM0 to the metal line BM1. Similarly, a metal line BMX−1 may be embedded in the IMD layer 148, and a metal line BMX may be embedded in the IMD layer 152, where a via BVX interconnects the metal line BMX−1 to the metal line BMX. In some embodiments, each IMD layers 140-152 includes multiple dielectric layers each encapsulating a via (e.g., the vias BV0, BV1, and BVX, etc.) and a corresponding metal line (e.g., the metal lines BM0, BM1, BMX−1, and BMX, etc.). Referring to FIG. 4, additional backside metallization layers including conductive features such as BVX+1, BMX+1, BVX+2, and BMX+2, etc., may be formed over the IMD layer 152 on the backside 102B.

In the present embodiments, the device 100A further includes the TSV 190 having at least a portion extending through the substrate 102 to electrically couple components disposed on the frontside 102F to those disposed on the backside 102B. In the depicted embodiments, the TSV 190 electrically couples a top portion of the BSLs 20 (e.g., the via BV0) to the FSLs 15 (e.g., the metal line M0). In this regard, the TSV 190 may extend through at least the substrate 102, the isolation structures 108, the ILD layer 117, and the IMD layer 120. The TSV 190 may be alternatively referred to as an interconnect conductive feature.

In some embodiments, the TSV 190 has a structure and composition similar to that of the vias, e.g., the vias V0 and V1, of the FSLs 15 (or the vias of the BSLs 20). For example, the TSV 190 includes a conductive fill layer 192 having a conductive material such as W, Cu, Co, Ru, Al, Ti, Ta, Au, Ag, Pt, other suitable conductive materials, or combinations (or alloys) thereof. In some embodiments, the TSV 190 further includes a barrier layer 194 separating the conductive fill layer 192 from the surrounding components. The barrier layer 194 may include Ti, Ta, TiN, TaN, other suitable materials, or combinations thereof. In some examples, the TSV 190 may be formed as a monolithic structure that extends from the substrate 102 to the metal line M0.

Each backside IMD layer and the corresponding conductive features embedded therein are collectively referred to as a backside metallization layer. For example, the IMD layer 140, the via BV0, and the metal line BM0 are collectively referred to as the zeroth backside metallization layer; the IMD layer 144, the via BV1, the metal line BM1 are collectively referred to as the first backside metallization layer; and so on. Referring to FIG. 4, additional backside metallization layers including conductive features such as BVX+1, BMX+1, BVX+2, and BMX+2, etc., may be formed over the IMD layer 152 on the backside 102B. In some embodiments, the IMD layers 140-152 may include the same structure and and composition as the ILD/IMD layers 117, 120, 122 described herein, and the conductive features embedded in the IMD layers 140-152 (e.g., BV0, BM0, BV1, BM1, . . . etc.). may include the same composition and structure as the conductive features embedded in the IMD layers 120, 122 (e.g., V0, M0, V1, M1, . . . etc.).

In some embodiments, the serially coupled BSM 40 and BST 60 form a backside memory cell (BSMC) having a 1T1C structure, such as BSMC1 and BSMC2 as depicted in FIG. 1. In this regard, the BSM 40 is configured as a capacitor (C) of the BSMC and the BST 60 is configured as a transistor (T) of the BSMC. In some embodiments, the BSM 40 serves as a storage unit of the BSMC, while the BST 60 serves as a switch to allow access (e.g., program, read, erase, etc.) to the BSM 40 in the BSMC. In some embodiments, the BSM 40 and the BST 60 are electrically coupled by a portion of the BSLs 20, such as the metal line BMX−1 depicted in FIG. 1.

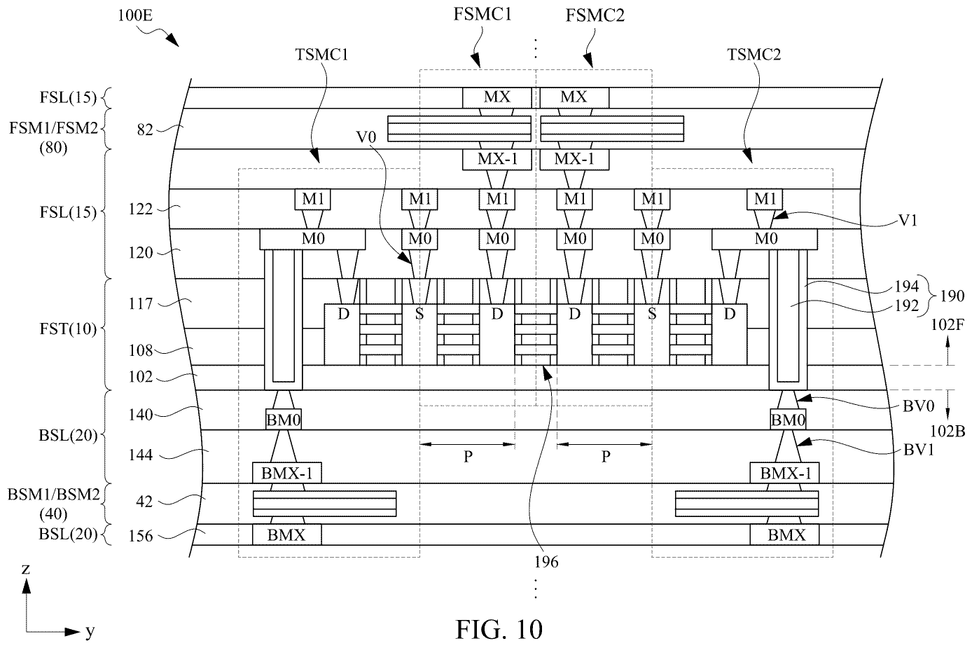

In the present embodiments, the BST 60 includes a metal oxide-based semiconductor material as the channel of the transistor, which differs from the channel of the FST 10. From a functionality perspective, the BST 60, if coupled to the BSM 40 in series, as depicted in FIGS. 1 and 2, is configured as the transistor portion of the BSMC. In contrast, the FST 10, if not coupled to the BSM 40 in series (but in parallel, for example), may be configured as a logic device on the frontside 102F (e.g., as a part of the logic portion of the device depicted in FIGS. 1 and 2). Alternatively, the FST 10, if coupled to the BSM 40 in series though at least the TSV 190, may be configured as the transistor portion of a memory cell (e.g., the trans-substrate memory cell described below) as described in detail below with reference to FIGS. 8-10 and 12.

As depicted herein, an entirety of the 1T1C structure is formed on the backside 102B and electrically coupled to the BSLs 20, which is subsequently coupled to the FSLs 15 through the TSV 190. In this regard, the BSMCs, which constitute at least a part of the memory portion of the device 100A, are provided entirely on the backside 102B, thereby increasing utilization of the space of the backside 102B as well as allowing more devices (e.g., devices of the logical and/or memory portions of the 100A) with reduced dimensions, for example, to be formed on the frontside 102F. For example, as will be described in detail below, additional memory cells may be formed on the frontside 102F with the BSMs 40 formed on the backside 102B. Accordingly, greater device density on both sides of the device 100A may be achieved. Furthermore, placing at least a part of the memory portion on the backside 102B permits additional routing from the backside 102B, thereby increasing flexibility in routing options for the device and relaxing design rules for the frontside components (e.g., the FSTs 10 and the FSLs 15).

Depending upon the types of material(s) employed in the BSM 40, the BSMC may include a dynamic random-access memory (DRAM) cell, a magnetoresistive random-access memory (MRAM) cell (also referred to as a magnetic tunnel junction, or MTJ, cell), a resistive random-access memory (ReRAM) cell, a ferroelectric random-access memory (FeRAM) cell, the like, or other suitable types of memory cells that have been, are being, or will be developed. In some embodiments, the device 100A may include two or more of the same or different types of BSMCs that each include at least the BSM 40. In some embodiments, referring to FIG. 1, the BSMC1 and BSMC2 are formed in the same IMD layer, e.g., IMD layer 42.

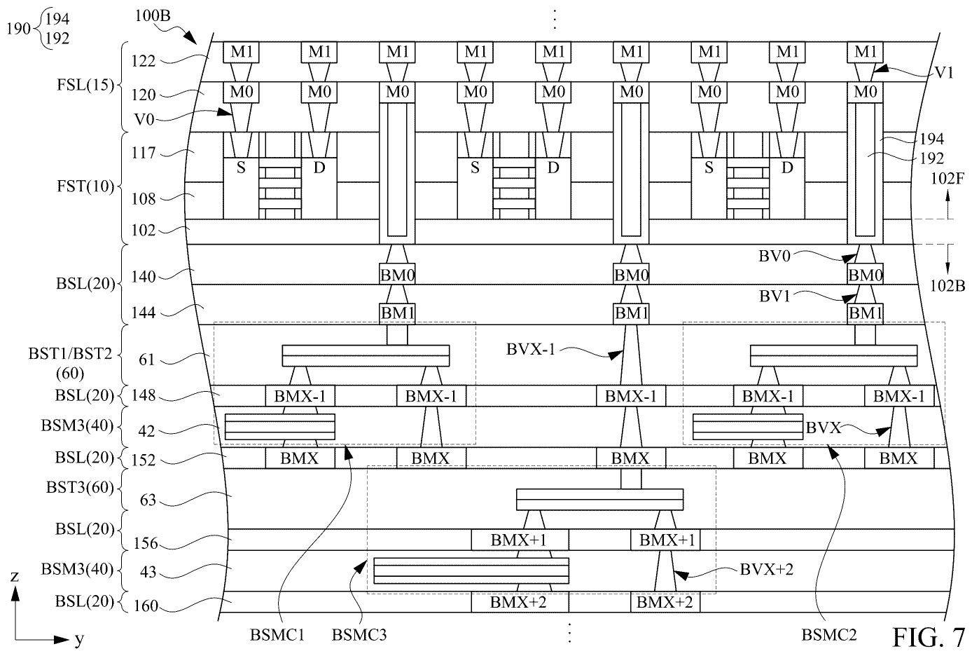

In some embodiments, referring to FIGS. 1 and 5, the BSM 40 is configured as a capacitor having a metal-insulator-metal (MIM) structure. In this regard, the BSM 40 generally includes a bottom electrode 44 (e.g., a first metal layer), a top electrode 48 (e.g., a second metal layer), and a dielectric layer 46 (e.g., an insulating layer) sandwiched between the bottom electrode 44 and the top electrode 48 along the vertical direction. The BSM 40 may further include a first via 50, which electrically couples the bottom electrode 44 to portions of the BSLs 20 below the BSM 40, and a second via 52, which electrically couples the top electrode 48 to portions of the BSLs 20 above the BSM 40.

The bottom electrode 44 and the top electrode 48 may include iron (Fe), W, Cu, Co, Ru, Al, Ti, Ta, Au, Ag, Pt, other suitable conductive materials, or combinations (or alloys) thereof.

In some embodiments, the bottom electrode 44 and the top electrode 48 may include a metal doped with a dopant (or impurity). The dielectric layer 46 may include any suitable dielectric materials, such as silicon dioxide, ZrO, TiO2, MgO, a high-k dielectric material described herein, other suitable dielectric materials, or combinations thereof. Examples of high-k dielectric materials include, but are not limited to, zirconium dioxide, hafnium dioxide, zirconium silicate, hafnium silicate, or the like. The first via 50 and the second via 52 may have the same composition and structure as that of the vias V0 and V1 described herein.

For embodiments in which the BSMC is a MRAM cell, the bottom electrode 44 and the top electrode 48 may each include a ferromagnetic material having, for example, Fe doped with Co, boron (B), nickel (Ni), other suitable dopants, or combinations thereof, and the dielectric layer 46 includes, for example, magnesium oxide (MgO). For embodiments in which the BSMC is a FeRAM cell, the dielectric layer 46 includes a ferroelectric material. Though not depicted herein, other capacitor configurations, e.g., MOS capacitor, may also be applicable for the present embodiments of the BSM 40.

In some examples, referring to FIG. 1, the BST 60 may include a metal-oxide-semiconductor field-effect transistor (MOSFET), a complementary metal-oxide-semiconductor (CMOS) transistor, a p-channel metal-oxide semiconductor (PMOS), an n-channel metal-oxide semiconductor (NMOS), a bipolar junction transistor (BJT), a high voltage transistor, a high frequency transistor, a fin-like FET (FinFET), a planar MOSFET, a nanosheet/nanowire FET (e.g., a GAA FET), the like, or other suitable types of memory cells that have been, are being, or will be developed. The BST 60 may sometimes be referred to as a back-gate transistor. In some embodiments, the device 100A may include two or more of the same or different types of the BST 60 each coupled in series with a corresponding BSM 40 to form one of the BSMCs. In the depicted embodiments, the BST 60 is embedded in an IMD layer 61, which may have the same structure and composition as the IMD layers 140-152 described herein.

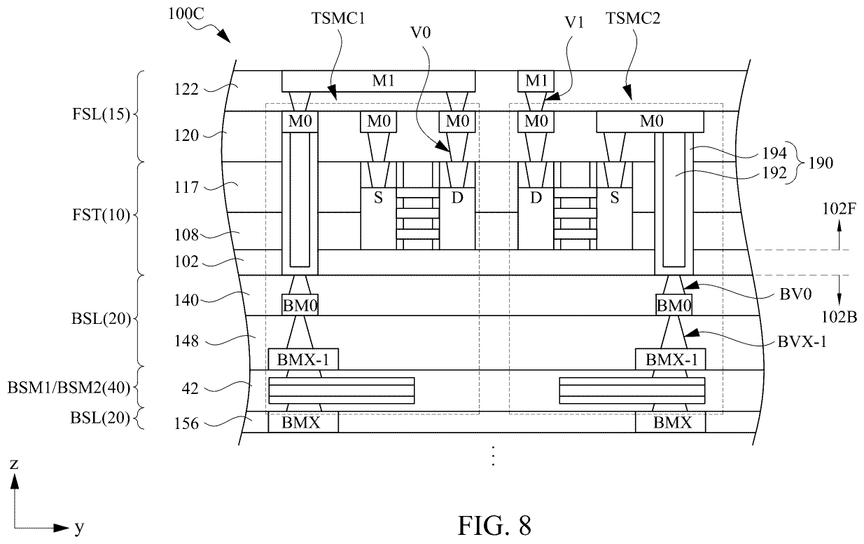

In some embodiments, referring to FIGS. 1 and 6 collectively, the BST 60 includes a channel layer 62 having a metal oxide semiconductor material. The BST 60 includes source electrode 64S and a drain electrode 64D (collectively referred to as source/drain electrodes 64) each extending from a respective end of the channel layer 62 along the vertical direction. In some embodiments, at least one of the source/drain electrodes 64 (e.g., the drain electrode 64D) is electrically coupled to the BSM 40 (e.g., the top electrode 48) through a portion of the BSLs 20 (e.g., the metal line BMX−1) and the second via 52. The BST 60 further includes a gate dielectric layer 66 overlaying the channel layer 62 and a gate electrode 68 disposed over the gate dielectric layer 66. In some embodiments, the gate electrode 68 is electrically coupled to portions of the BSLs 20 (e.g., the metal line BM1) disposed above the BST 60. In the present embodiments, the gate electrode 68 is electrically coupled to the FSLs 15 through the portions of the BSLs 20 and the TSV 190.

The channel layer 62 may include one or more metal oxide semiconductor materials, such as indium gallium zinc oxide (IGZO), zinc oxide (ZnO), indium oxide (In2O3), tin (IV) oxide (SnO2), nickel oxide (NiO), copper oxide (Cu2O), copper aluminum oxide (CuAlO2), copper gallium oxide (CuGaO2), copper indium oxide (CuInO2), strontium, copper oxide (SrCu2O2), tin (II) oxide (SnO), other suitable indium tin oxide (ITO), indium zinc oxide (IZO), indium tungsten oxide (IWO), polysilicon, amorphous silicon, other suitable materials, or combinations thereof. The channel layer 62 may include an n-type channel material or a p-type channel material. The gate dielectric layer 66 may include any silicon oxide, silicon oxynitride, a high-k dielectric material described herein, other suitable dielectric materials, or combinations thereof. In some embodiments, the gate dielectric layer 66 has the same composition as the dielectric layer 46 of the BSM 40. The source/drain electrodes 64 and the gate electrode 68 may each include W, Cu, Co, Ru, Al, Ti, TiN, Ta, TaN, Au, Ag, Pt, other suitable conductive materials, or combinations (or alloys) thereof.

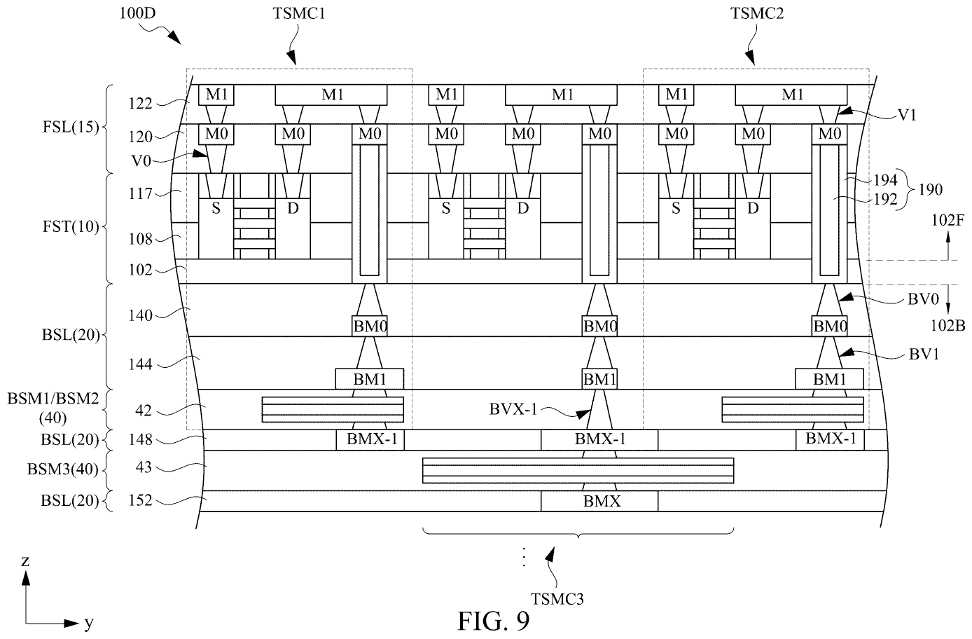

FIG. 7 illustrates a cross-sectional view of an example semiconductor device 100B (alternatively referred to as a memory device), in portion or in entirety, according to some embodiments of the present disclosure. The semiconductor device 100B (or “device” for short) may be configured to have a structure similar to that of the device 100A. For example, the device 100B includes multiple BSMCs, e.g., BSMC1, BSMC2, and BSMC3, disposed on the backside 102B and configured as a memory portion of the device 100B. Each of the BSMCs includes the BSM 40 electrically coupled to the BST 60 in series in a 1T1C structure described herein. The device 100B includes multiple FSTs 10 on the frontside 102F configured as logic devices in a logic portion of the device 100B. Furthermore, each of the BSMCs is electrically coupled to the FSLs 15 through the TSV 190.

Regarding the arrangement of the BSMCs, however, the device 100B differs from the device 100A. For example, rather than extending through the same IMD layer, the BSMC1 and BSMC2 each extends through (or occupy) the IMD layers 61, 148, and 42, while the BSMC3 extends through (or occupy) IMD layers 63, 156, and 43, which are below (e.g., at a location distal to the substrate 102) the IMD layers 61, 148, and 42. In some examples, placing different memory cells in different IMD layers may increase the utilization of different portions (e.g., horizontal levels) of the backside 102B, thus further improving the device density (e.g., memory device) on at least the backside 102B of the device 100B. In some examples, by staggering the positions of the BSMCs on the backside 102B, limitation on sizes of the memory cells may be relaxed, allowing the BSTs 60 and/or the BSMs 40 to be formed to larger areas, for example, for improved device performance.

FIG. 8 illustrates a cross-sectional view of an example semiconductor device 100C (alternatively referred to as a memory device), in portion or in entirety, according to some embodiments of the present disclosure. The semiconductor device 100C (or “device” for short) may be configured to have a structure similar to that of the device 100A. For example, the device 100C includes multiple BSMs 40, e.g., BSM1 and BSM2, disposed on the backside 102B. The device 100B includes multiple FSTs 10 on the frontside 102F. Furthermore, the device 100B includes the TSV 190 through which each of the BSLs 20 are electrically coupled to the FSLs 15.

However, the arrangement of the memory portion of the device 100C differs from that of the device 100A. For example, each of the BSMs 40 is electrically coupled to one of the FSTs 10 in series, thereby forming a trans-substrate memory cell (TSMC), e.g., TSMC1 and TSMC2, as the memory portion of the device 100C. Each TSMC has a 1T1C structure similar to the BSMC of the device 100A. In this regard, the capacitor portion of the TSMC is disposed on the backside 102B and the transistor portion of the TSMC is disposed on the frontside 102F, such that the memory portion of the device 100C spans across both the frontside 102F and the backside 102B of the substrate 102.

In the depicted embodiment, the BSM 40 is electrically coupled to the corresponding FST 10 through portions of the BSLs 20, the TSV 190, and a portion of the FSLs 15. For example, the TSMC1 includes the BSM 40 coupled to portions of the BSLs 20 (e.g., the metal lines BMX−1 and BM0 and the vias BVX−1 and BV0), which are coupled to the metal line M1 of the FSLs 15 through the TSV 190 and portions of the FSLs 15 (e.g., the vias V0 and V1, and the metal line M0). The metal line M1 is further coupled to the drain feature 14D of the corresponding FST 10 through other portions of the FSLs 15 and the source/drain contacts 18, thereby establishing the serial coupling between the BSM 40 and the FST 10. Similarly, the TSMC2 includes the BSM 40 coupled to portions of the BSLs 20, which are coupled to the metal line M0 of the FSLs 15 through the TSV 190. The metal line M0 is further coupled to the drain feature 114D of the corresponding FST 10 through a portion of the FSLs 15 (e.g., the via V0) and the S/D contact 18.

While not depicted in FIG. 8, the device 100C may further include various logic devices disposed on the frontside 102F, thereby allowing both sides of the substrate 102 to be utilized for increased device density. In some examples, the logical devices may include FSTs 10 disposed on the frontside 102F but not electrically coupled to the BSMs 40 in series.

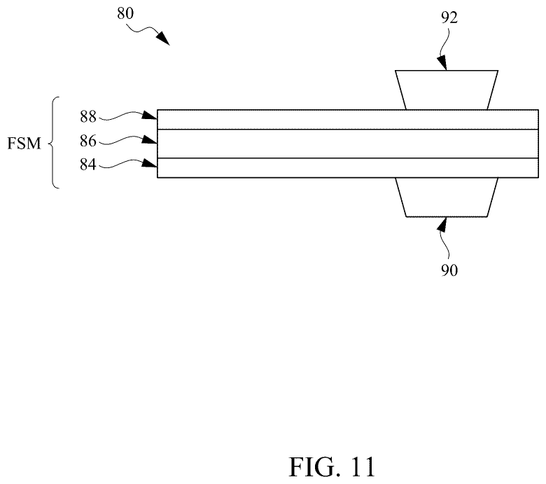

FIG. 9 illustrates a cross-sectional view of an example semiconductor device 100D (alternatively referred to as a memory device), in portion or in entirety, according to some embodiments of the present disclosure. The semiconductor device 100D (or “device” for short) may be configured to have a structure similar to that of the device 100C. For example, the device 100D includes multiple TSMCs, e.g., TSMC1, TSMC2, and TSMC3, configured as a memory portion of the device 100D. In this regard, the capacitor portion of each TSMC is disposed on the backside 102B and the transistor portion of the TSMC is disposed on the frontside 102F, similar to that depicted in FIG. 8. In the depicted embodiment, each of the TSMCs of the device 100D includes the BSM 40 electrically coupled to the corresponding FST 10 through at least portions of the BSLs 20, the TSV 190, and the metal line M1 of the FSLs 15.

Regarding the arrangement of the TSMCs, however, the device 100D differs from the device 100C. For example, rather than being disposed in the same IMD layer, as in the example of the device 100C, the BSMs 40 of the TSMC 1 and TSMC2 are disposed in the IMD layer 42, while the TSMC3 is disposed in the IMD layer 43, which is below (e.g., at a location distal to the substrate 102) the IMD layer 42. In contrast, the BSMs 40 of both the TSMCs of the device 100C are disposed in the IMD layer 42. As described herein, placing different memory cells, or portions thereof, in different IMD layers may increase the utilization of different portions (e.g., horizontal levels) of the backside 102B, thus further improving the device density on at least the backside 102B of the device 100D. In some examples, by staggering the positions of the BSMs 40 on the backside 102B, limitation on sizes of the memory cells may be relaxed, allowing the BSMs 40 to be formed to larger areas, for example, for improved device performance.

FIG. 10 illustrates a cross-sectional view of an example semiconductor device 100E (alternatively referred to as a memory device), in portion or in entirety, according to some embodiments of the present disclosure. The semiconductor device 100E (or “device” for short) may be configured to have a structure similar to that of the device 100C. For example, the device 100E includes multiple TSMCs, e.g., TSMC1 and TSMC2, configured as a memory portion of the device 100E. In this regard, the capacitor portion of each TSMC is disposed on the backside 102B and the transistor portion of the TSMC is disposed on the frontside 102F, similar to that depicted in FIG. 8. In the depicted embodiment, each of the TSMCs of the device 100E includes the BSM 40 electrically coupled to the corresponding FST 10 through at least portions of the BSLs 20, the TSV 190, and the metal line M0 of the FSLs 15.

However, different from the device 100C, the device 100E further includes multiple frontside memory cells (FSMCs), e.g., FSMC1 and FSMC2, configured as the memory portion of the device 100E in addition to the TSMC 1 and TSMC 2. In the depicted embodiment, the FSMC1 and FSMC2 each include an FST 10 electrically coupled to a corresponding frontside memory element 80 (FSM) in series, where the FSM 80 is disposed in an IMD layer 82.

Specially, the FSM 80 is electrically coupled to the drain feature 14D of the corresponding FST 10, thereby establishing the serial connection therebetween.

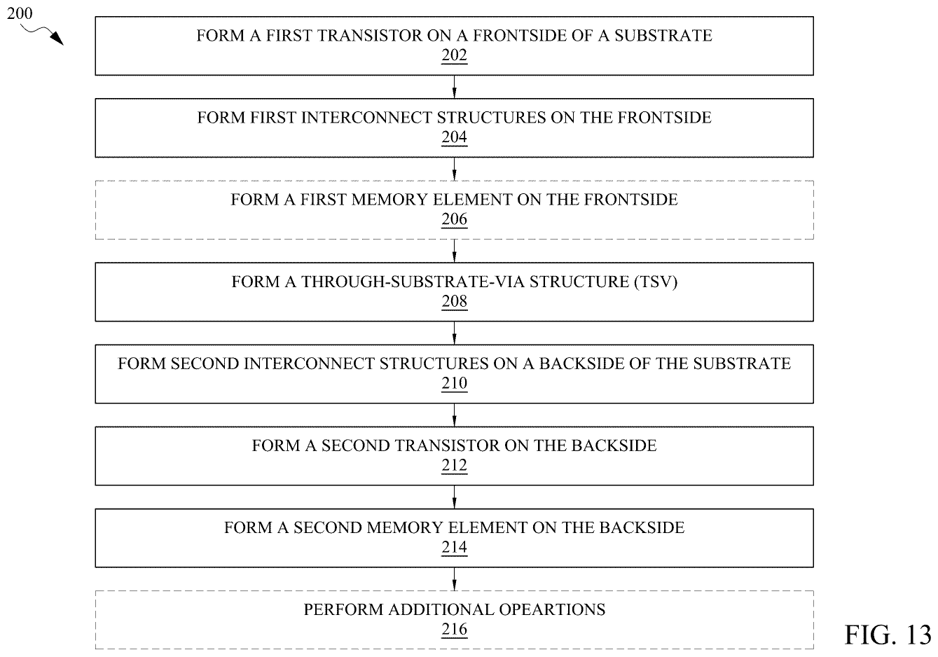

In some embodiments, the FSM 80 has a structure and composition similar to that of the BSM 40. For example, referring to FIG. 11, the FSM 80 includes an MIM capacitor structure having a bottom electrode 84 (e.g., a first metal layer), a top electrode 88 (e.g., a second metal layer), and a dielectric layer 86 (e.g., an insulating layer) sandwiched between the bottom electrode 84 and the top electrode 88 along the vertical direction. The FSM 80 may further include a first via 90, which electrically couples the bottom electrode 84 to portions of the FSLs 15 below the FSM 80 (e.g., the vias V0, V1, and VX−1, and the metal lines M0, M1, and MX−1), and a second via 92, which electrically couples the top electrode 88 to portions of the FSLs 15 above the FSM 80 (e.g., the metal line MX). As the FSMC has a 1T1C structure, both the transistor and the capacitor portion of each FSMC are disposed on the frontside 102F.

Accordingly, both the frontside 102F and the backside 102B are utilized to form the memory portion of the device 100E, potentially achieving greater device density than that of the device 100C. In some examples, though not depicted, the BSMs 40 of the TSMCs may be formed in different IMD layers, similar to the device 100D, to allow staggering of the BSMs 40 on the backside 102B.

In some embodiments, the TSMC1 and an adjacent FSMC 1 are configured to share a common source feature, such as the source feature 14S, thereby allowing the frontside devices (e.g., the FSMCs) to have a more compact dimension along the first lateral direction. For example, a cell dimension may be reduced to 1.5 times a lateral dimension of the FST 10 (P=1.5 T), which is in contrast to a cell dimension of 2 times the lateral dimension of the FST 10 (P=2 T) in embodiments where the source feature 14S is not shared between adjacent memory cells. To accommodate the sharing of the source feature, the device 100E may further include a dummy gate structure 196 (alternatively referred to as an inactive gate) disposed between drain features, such as the drain features 14D, of the two adjacent FSMCs, where the dummy gate structure 196 is grounded (or electrically coupled to a supply voltage of 0V). The dummy gate structure 196 may have similar structure and composition as the active gate structure 16 but is not electrically coupled to any signal line, as is the case for the active gate structures 16.

FIG. 12 illustrates a cross-sectional view of an example semiconductor device 100F (alternatively referred to as a memory device), in portion or in entirety, according to some embodiments of the present disclosure. The semiconductor device 100F (or “device” for short) may be configured to have a structure similar to that of the device 100E. For example, the device 100F includes multiple TSMCs, e.g., TSMC1 and TSMC2, configured as a memory portion of the device 100F. The device 100F further includes multiple FSMCs, e.g., FSMC1 and FSMC2, configured as an additional memory portion of the device 100F. Furthermore, the adjacent FSMC and TSMC are configured to share a common source feature, such as the source feature 14S, thereby reducing the lateral dimension of the frontside devices (e.g., the FSMCs) to 1.5 T, similar to that depicted in FIG. 10.

However, different from the device 100E, the device 100F includes a dielectric structure 198 (alternatively referred to as an isolation gate) interposed between the drain features 14D of the two adjacent FSMCs. In some embodiments, the dielectric structure 198 may be formed as a cut-poly-on-diffusion-edge (CPODE) feature, which generally replaces an active gate structure 16 between the drain features 14D two adjacent transistors. The dielectric structure 198 may include any dielectric material, such as silicon oxide, silicon nitride, silicon oxynitride, other suitable dielectric materials, or combinations thereof. In some embodiments, the dielectric structure 198 may be formed in place of an active gate structure 16 after formation of all active gate structures 16 on the frontside 102F is completed. In some embodiments, the dielectric structure 198 and the dummy gate structure 196 each serve the function of electrically isolating adjacent frontside devices, such as the FSMCs 1 and 2. In some examples, the dielectric structure 198 and the dummy gate structure 196 may be employed interchangeably.

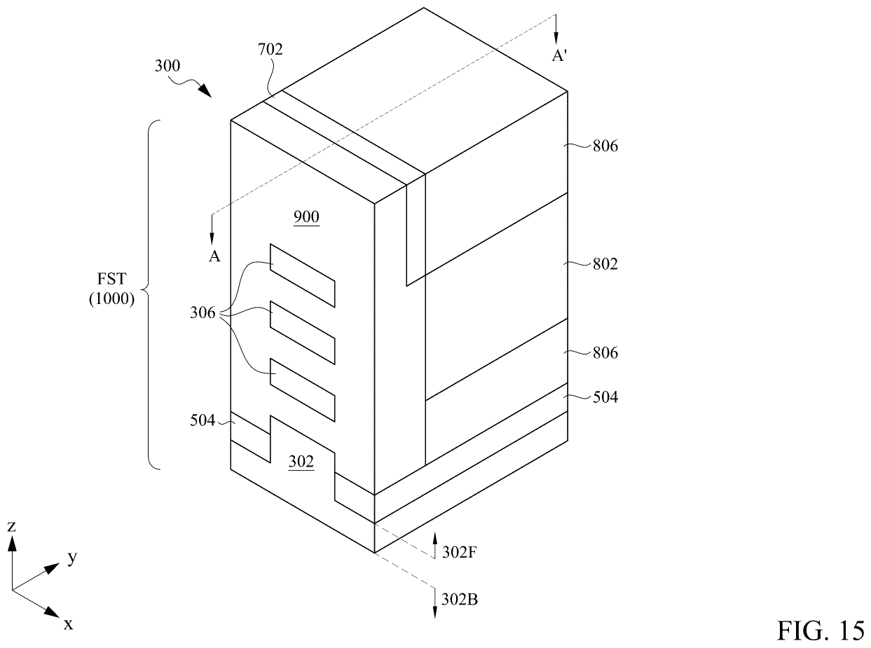

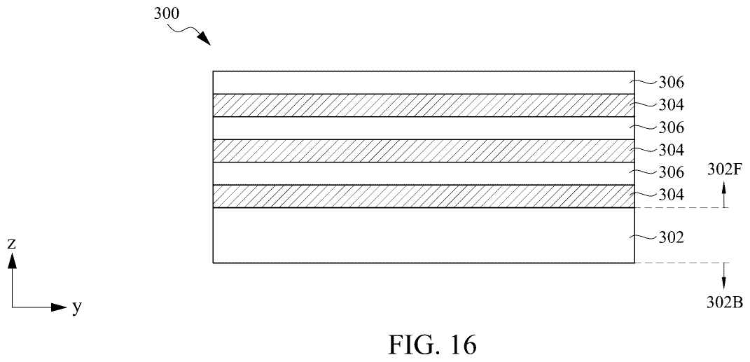

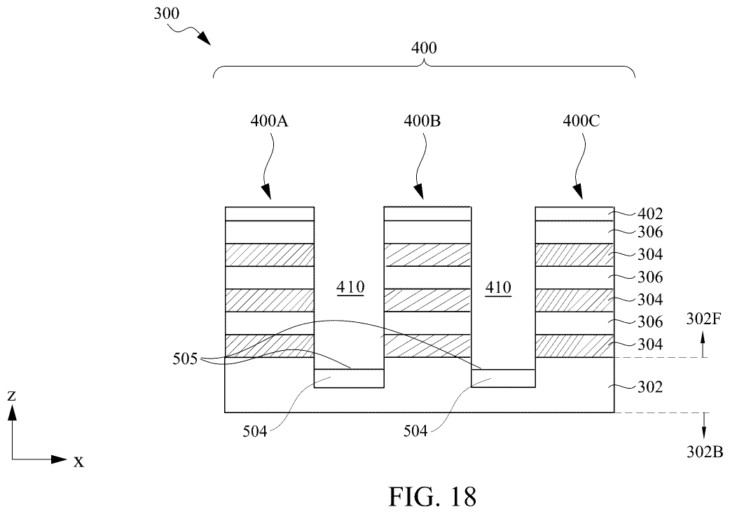

FIG. 13 illustrates a flow chart of an example method 200 for making a semiconductor device 300 (e.g., the device 100A-100F) in accordance with some embodiments. It should be noted that the method 200 is merely an example and is not intended to limit the present disclosure. Accordingly, it is understood that additional steps/operations may be provided before, during, and after the method 200 of FIG. 13, and that some other operations may only be briefly described herein. In some embodiments, operations of the method 200 are described in detail in a flow chart illustrated in each of FIGS. 14, 24, and 25. Operations of the method 200 may be associated with cross-sectional views of the semiconductor device 300 at various fabrication stages as shown in FIGS. 16-33, which will be described in further detail below.

In brief overview, referring to FIG. 13, the method 200 begins with operation 202 of forming a first transistor (or frontside transistor, FST, e.g., the FST 10, 1000) on a frontside (or a frontside, e.g., 102F, 302F) of a substrate (e.g., the substrate 102, 302). The method 200 proceeds to operation 204 of forming first interconnect structures (or frontside interconnect structures, FSLs, e.g., the FSLs 15, 1100) on the frontside. The method 200 optionally proceeds to operation 206 of forming a first memory element (or frontside memory element, FSM, e.g., the FSM 80, 1200) on the frontside. The method 200 proceeds to operation 208 of forming a through-substrate-via structure (TSV; e.g., the TSV 190, 920). Next, the method 200 proceeds to operation 210 of forming second interconnect structures (or backside interconnect structures, BSLs, e.g., the BSLs 20, 1300) on a backside (or a second side, e.g., the backside 102B) of the substrate opposite to the frontside. The method 200 optionally proceeds to operation 212 of forming a second transistor (or a backside transistor, BST, e.g., the BST 60, 1600) on the backside. The method 200 proceeds to operation 214 of forming a second memory element (or a backside memory element, BSM, e.g., the BSM 40, 1400) on the backside. In some embodiments, the second memory element is electrically coupled to the second transistor in series on the second side (see FIGS. 1 and 7). In some embodiments, the second memory element is electrically coupled to the first transistor in series (see FIGS. 8-10 and 12).

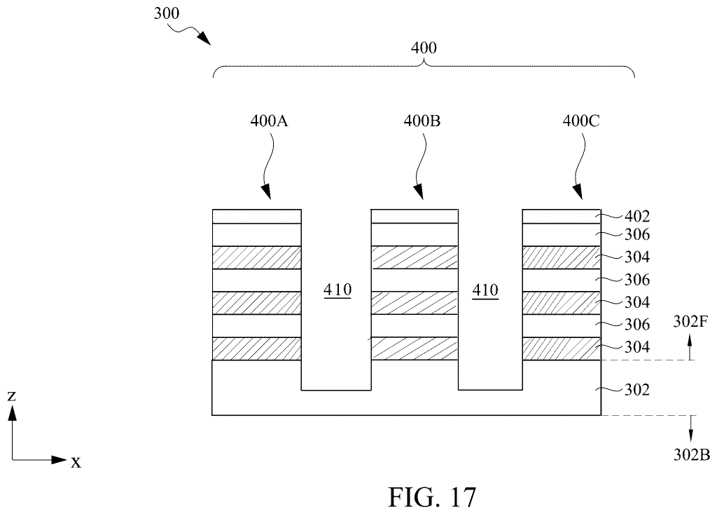

FIG. 15 illustrates a perspective view of a portion of an example semiconductor device 300 (or “device” for short), which includes at least an example frontside transistor 1000 (FST) depicted herein on a frontside of the device 300, in accordance with some embodiments. In some embodiments, the FST 1000 is fabricated at the operation 202 of the method 200, which is described in detail by the flow chart illustrated in FIG. 14.

The device 300 includes a substrate 302 and a number of semiconductor layers 306 (e.g., the nanostructures 13) above the substrate 302 (e.g., the substrate 102). The semiconductor layers 306 may be alternatively configured as nanosheets, nanorods, nanowire, or other suitable nanostructures. The semiconductor layers 306 are vertically separated from one another, which collectively function as channels of the FST 1000. Isolation regions/structures 504 (e.g., the isolation structures 108) are formed on sidewalls of a protruding portion of the substrate 302, with the semiconductor layers 306 disposed above the protruding portion. An active gate structure 900 (e.g., the active gate structures 16) wraps around each of the semiconductor layers 306 (e.g., a full perimeter of each of the semiconductor layers 306). Source/drain features 802 (e.g., the source/drain features 14), one of which is depicted in FIG. 15, are disposed on opposing sides of the active gate structure 900 with the gate spacers 702 disposed therebetween. An interlayer dielectric (ILD) 806 is disposed over and may extend below a portion of the source/drain features 802. The FST 1000 (i.e., the device 300) shown in FIG. 15 is simplified, and thus, it should be understood that one or more features of a completed FST 1000 may not be shown in FIG. 15. For example, the other one of the source/drain features 802 is not depicted in FIG. 15. Further, FIG. 15 is provided as a reference to illustrate a number of cross-sectional views of the device 300 along line AA′, which extends along the first lateral direction, in the subsequent figures.

In brief overview, referring to FIG. 14, the FST 1000 may be formed by implementing sub-operations of the operation 202. For example, the operation 202 may begin with sub-operation 252 of providing the substrate 302 overlaid by first semiconductor layers 304 and second semiconductor layers 306. Next, the operation 202 proceeds to sub-operation 254 of forming fin structures 400. The operation 202 proceeds to sub-operation 256 of forming isolation structures 504. The operation 202 proceeds to sub-operation 258 of forming dummy gate structures 600 over the semiconductor fin. The operation 202 proceeds to sub-operation 260 of forming inner spacers (e.g., the inner spacers 11). The operation 202 proceeds to sub-operation 262 of forming source and/or drain features. The operation 202 proceeds to sub-operation 264 of removing dummy gate structures and the first semiconductor layers. The operation 202 proceeds to sub-operation 266 of forming active gate structures. The operation 202 may optionally proceed to sub-operation 268 of replacing some active gate structures with dielectric structures (e.g., the dielectric structure 198). The operation 202 proceeds to sub-operation 270 of forming contact features electrically coupled to components of the FST 1000.

Referring to FIGS. 14 and 16, a number of first semiconductor layers 304 and a number of second semiconductor layers 306 are alternatingly formed on top of one another over a frontside 302F of the substrate 302 at the sub-operation 252, in accordance with various embodiments. Such alternately stacked first semiconductor layers 304 and second semiconductor layers 306 may be formed as a stack over a frontside of the substrate 302. It should be understood that the FST 1000 can include any number of first semiconductor layers 304 (which respectively serve as sacrificial layers) and any number of second semiconductor layers 306 (which respectively serve as channel layers), with either one of them being the topmost layer, while remaining within the scope of the present disclosure.

In some embodiments, the substrate 302 has substantially the same structure and composition as the substrate 102 described herein. In some embodiments, the substrate 302 includes an epitaxial layer. For example, the semiconductor substrate 302 may have an epitaxial layer overlying a bulk semiconductor. Furthermore, the substrate 302 may include a semiconductor-on-insulator (SOI) structure. For example, the substrate 302 may include a buried oxide (BOX) layer formed by a process such as separation by implanted oxygen (SIMOX) or other suitable technique, such as wafer bonding and grinding.

The semiconductor layers 304 and 306 may have different thicknesses. The first semiconductor layers 304 may have different thicknesses from one layer to another layer. The second semiconductor layers 306 may have different thicknesses from one layer to another layer. The first layer of the stack may be thicker than other semiconductor layers 304 and 306. Either the first semiconductor layer 304 or the second semiconductor layer 306 may be the topmost layer (or the layer most distanced from the semiconductor substrate 302). In an embodiment, the first semiconductor layer 304 may be the bottommost layer (or the layer most proximate to the semiconductor substrate 302).

The semiconductor layers 304 and 306 have different compositions. In various embodiments, the two semiconductor layers 304 and 306 have compositions that provide for different oxidation rates and/or different etch selectivity between the layers. In an embodiment, the first semiconductor layers 304 include silicon germanium (Sil-xGex), and the second semiconductor layers 306 include silicon (Si). In some embodiments, the second semiconductor layers 306 have substantially the same composition as the nanostructures 13 described herein.

Either of the semiconductor layers 304 and 306 may include other materials, for example, a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GaInP, and/or GaInAsP, any other suitable material, or combinations thereof. The materials of the semiconductor layers 304 and 306 may be chosen to provide different oxidation rates and/or etch selectivity.

The semiconductor layers 304 and 306 can be grown from the semiconductor substrate 302. For example, each of the semiconductor layers 304 and 306 may be grown by a molecular beam epitaxy (MBE) process, a chemical vapor deposition (CVD) process such as a metal organic CVD (MOCVD) process, and/or other suitable growth processes. During the epitaxial growth, the crystal structure of the semiconductor substrate 302 extends upwardly, resulting in the semiconductor layers 304 and 306 having the same crystal orientation with the semiconductor substrate 302.

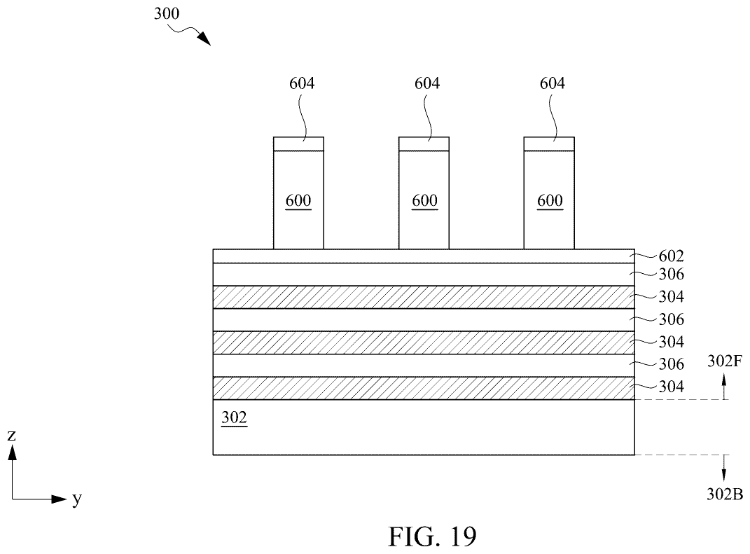

Referring to FIGS. 14 and 17, fin structures 400A, 400B, and 400C (collectively referred to as fin structures 400) are formed in the stack of the semiconductor layers 304 and 306 at the sub-operation 254, in accordance with various embodiments. The fin structures 400 are each elongated along the first lateral direction and spaced from one another along a second lateral direction (e.g., the X axis) perpendicular to the first lateral direction. Although three fin structures are shown in the illustrated embodiment of FIG. 17 (and the following figures), it should be appreciated that the FST 1000 can include any number of fin structures while remaining within the scope of the present disclosure.

The fin structures 400 are formed by patterning the stack of semiconductor layers 304 and 306 and a top portion of the substrate 302 using, for example, photolithography and etching techniques. For example, a mask layer (which can include multiple layers such as, for example, a pad oxide layer and an overlying pad nitride layer) is formed over the topmost second semiconductor layer 306. The pad oxide layer and the pad nitride layer may be formed using thermal oxidation, low-pressure chemical vapor deposition (LPCVD), or plasma enhanced chemical vapor deposition (PECVD), for example.

The mask layer may then be patterned using photolithography techniques. Generally, photolithography techniques utilize a photoresist material (not shown) that is deposited, irradiated (exposed), and developed to remove a portion of the photoresist material. The remaining photoresist material protects the underlying material, such as the mask layer in this example, from subsequent processing steps, such as etching. For example, the photoresist material is used to pattern the pad oxide layer and pad nitride layer to form a patterned mask 402, as illustrated in FIG. 17. The photoresist material may be removed by a suitable method, such as plasma ashing or resist stripping, after patterning the mask layer.

The patterned mask 402 is subsequently used to pattern exposed portions of the semiconductor layers 304 and 306 and the substrate 302 to form trenches (or openings) 410, thereby defining the fin structures 400 between adjacent trenches 410, as illustrated in FIG. 4.

The trenches 410 continuously extend along the first lateral direction. When multiple fin structures are formed, such a trench 410 may be disposed between any adjacent ones of the fin structures. In some embodiments, the fin structures 400 are formed by etching trenches in the semiconductor layers 304 and 306 and the substrate 302 using, for example, reactive ion etch (RIE), neutral beam etch (NBE), other suitable process, or combinations thereof. The etching process may be anisotropic.

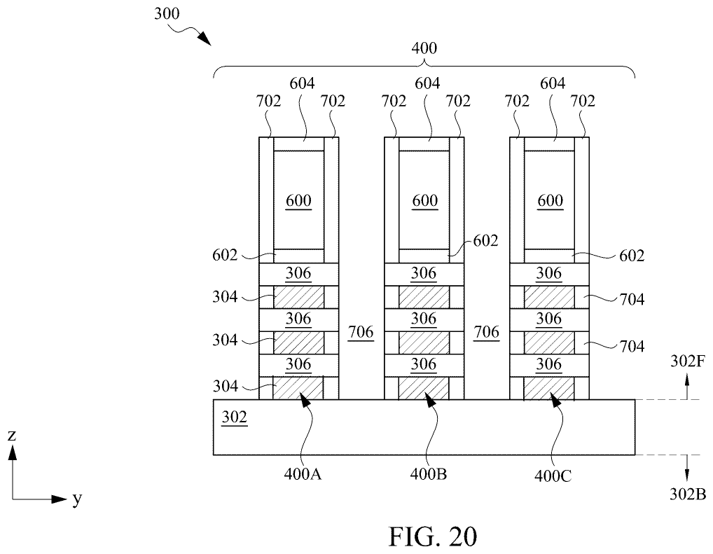

Referring to FIGS. 14 and 18, the isolation structures 504 (alternatively referred to as isolation regions) at the sub-operation 256, in accordance with various embodiments. As shown in FIG. 18, the isolation structures 504 can be formed between adjacent ones of the fin structures 400, and partially embed or surround lower portions of the adjacent fin structures 400.

In some embodiments, the isolation structures 504 have substantially the same composition as the isolation structures 108. The isolation structures 504 may be formed by first depositing an insulation material by high-density plasma chemical vapor deposition (HDP-CVD), flowable CVD (FCVD) (e.g., a CVD-based material deposition process in a remote plasma system and post curing to make it convert to another material, such as an oxide), other suitable methods, or combinations thereof. An anneal process may be performed once the insulation material is formed. A planarization process, such as a chemical mechanical polish (CMP) process or any other suitable process, may remove any excess insulation material and form a top surface of the insulation material and a top surface of the patterned mask 402 that are coplanar (not shown). The patterned mask 402 may be removed by the planarization process, in some other embodiments. Subsequently, the insulation material is recessed to form the isolation structures 504, which are sometimes referred to as shallow trench isolations (STIs). The isolation structures 504 are recessed such that the fin structures 400 protrude from between neighboring isolation structures 504. The isolation structures 504 may be recessed to where a top surface of the isolation structures 504 is below the substrate 302. The isolation structures 504 may be recessed using an acceptable etching process, such as one that is selective to the material of the isolation structures 504. For example, a dry etch or a wet etch using dilute hydrofluoric (DHF) acid may be performed to recess the isolation structures 504.

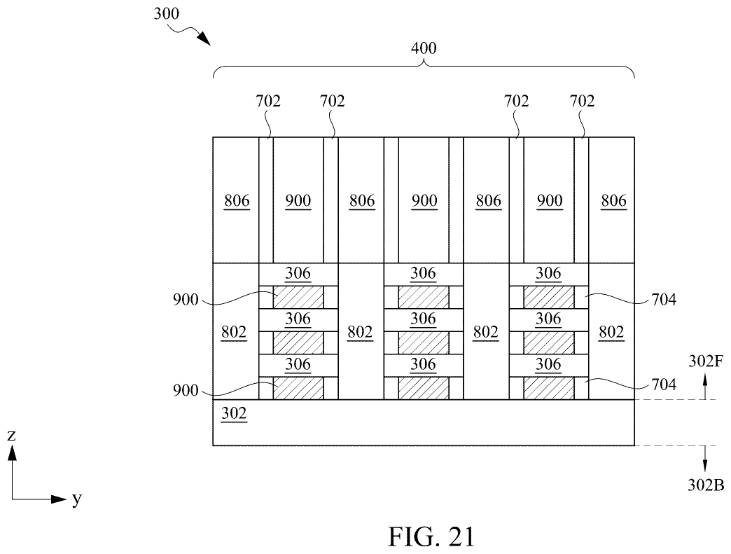

Referring to FIGS. 14 and 19, a number of dummy gates structures 600 are formed over the fin structures 400 at the sub-operation 258, in accordance with various embodiments. The dummy gate structures 600 each extend continuously along the second lateral direction and are placed where an active (e.g., metal) gate structure may later be formed. Three dummy gate structures 600 are shown in FIG. 19, but it is understood that any number of dummy gate structures 600 may be formed over the fin structures 400.

An etch-stop layer 602 may be formed over a top surface of the fin structure 400 before forming the dummy gate structures 600. The etch-stop layer 602 may include silicon oxide or any other suitable material and may be formed by a deposition process, such as CVD, ALD, another suitable processes, or a combination thereof. Then, a dummy gate electrode layer (not depicted) including polysilicon, for example, may be deposited over the etch-stop layer 602 as a blanket layer. In some embodiments, a hard mask 604 is deposited over the dummy gate electrode layer. The dummy gate electrode layer is then formed by first patterning the hard mask 604 using a photolithography process described herein and etching the dummy gate electrode layer using the patterned hard mask 604 as an etch mask.

In some embodiments, though not depicted, the dummy gate structures 600 each further include a dummy gate dielectric layer (not shown) disposed between the etch-stop layer 602 and the dummy gate electrode layer. The dummy gate dielectric layer may include, for example, silicon oxide, silicon nitride, silicon oxynitride, multilayers thereof, other suitable dielectric materials, or combinations thereof, and may be formed by thermal oxidation, chemical oxidation, CVD, ALD, other suitable methods, or combinations thereof.

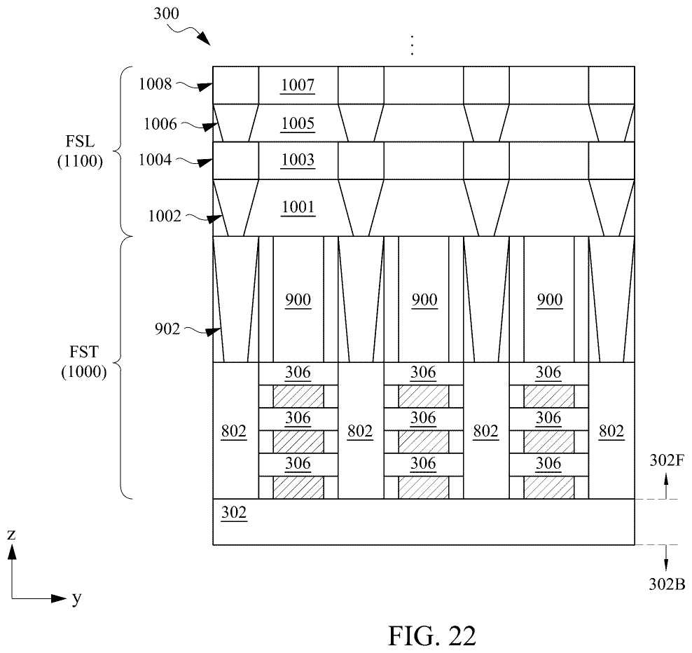

Referring to FIGS. 14 and 20, the gate spacers 702 are formed on opposing sidewalls of the dummy gate structures 600 at the sub-operation 260, in accordance with various embodiments. The gate spacers 702 may include any suitable dielectric materials as described herein with respect to the gate spacers 17. In some embodiments, the gate spacers 702 include multiple layers of different dielectric materials. The gate spacers 702 may be formed by first conformally depositing one or more dielectric materials over the dummy gate structures 600.

Any suitable deposition method, such as thermal oxidation, chemical oxidation, CVD, ALD, other suitable methods, or combinations thereof, may be used to deposit the dielectric materials. Then, the dielectric material(s) may be etched by a suitable etching process, such as an anisotropic dry etching process, to form the gate spacers 702 along the opposing sidewalls of the dummy gate structures 600.

Referring to FIGS. 14 and 20, the source/drain features 802 are formed in each fin structure 400 on respective sides of the dummy gate structure 600 at the sub-operation 262, in accordance with various embodiments. The source/drain features 802 may be formed by performing an etching process to remove portions of the fin structures 400 that are not covered by the dummy gate structures 600 and the gate spacers 702. The etching process may include an anisotropic etching process using the dummy gate structures 600 as an etching mask, although any other suitable etching process may also be used. Upon the portions of the fin structures 400 being removed, source/drain recesses 706 are formed.

Concurrent with or subsequent to the formation of the source/drain recesses 706, respective end portions of each of the first semiconductor layers 304 may be removed or etched. The end portions of the first semiconductor layers 304 can be removed using a “pull-back” process to pull the first semiconductor layers 304 by an initial pull-back distance such that the ends of the first semiconductor layers 304 terminate underneath (e.g., aligned with) the gate spacers 702. It is understood that the pull-back distance (i.e., the extent to which each of the semiconductor layers 304 is etched or pulled-back) can be arbitrarily increased or decreased.

Due to the etching selectivity between the first semiconductor layers 304 and the second semiconductor layers 306, the second semiconductor layers 306 remain substantially intact during this etching process.

Next, inner spacers 704 are formed on the exposed end portions of the first semiconductor layers 304 in the source/drain recesses 706. The inner spacers 704 may include any suitable dielectric materials as described herein with respect to the inner spacers 11 described herein. The inner spacers 704 may be formed by depositing one or more layers of dielectric materials over the exposed end portions of the first semiconductor layers 304 by CVD, ALD, physical vapor deposition (PVD), other suitable methods, or combinations thereof. The dielectric material(s) may then be etched by an isotropic or anisotropic etching process to remove excess dielectric material(s) from the sidewalls of second semiconductor layers 306 and the top surface of the semiconductor substrate 302.

Subsequently, the source/drain features 802 are formed in the source/drain recesses 706 over the inner spacers 704. The source/drain features 802 may include any suitable semiconductor materials as described herein with respect to the source/drain features 14. In some embodiments, the source/drain features 802 are aligned with the ends of the inner spacers 704 and the second semiconductor layers 306. The source/drain features 802 may be formed using an epitaxial layer growth process on exposed ends of each of the second semiconductor layers 306. For example, the growth process may include a selective epitaxial growth (SEG) process, CVD deposition techniques (e.g., vapor-phase epitaxy (VPE) and/or ultra-high vacuum CVD (UHV-CVD)), molecular beam epitaxy, other suitable epitaxial processes, or combinations thereof. In some other embodiments, the bottom surface of the source/drain features 802 may be lower than a top surface of the isolation structure 504.

In-situ doping (ISD) may be applied to form doped source/drain features 802, thereby creating the junctions for the FST 1000. For example, when the FST 1000 is configured as an n-type device, the source/drain features 802 may include Si doped with an n-type dopant described herein. When the FST 1000 is configured as a p-type device, the source/drain features 802 may include SiGe doped with a p-type dopant described herein.

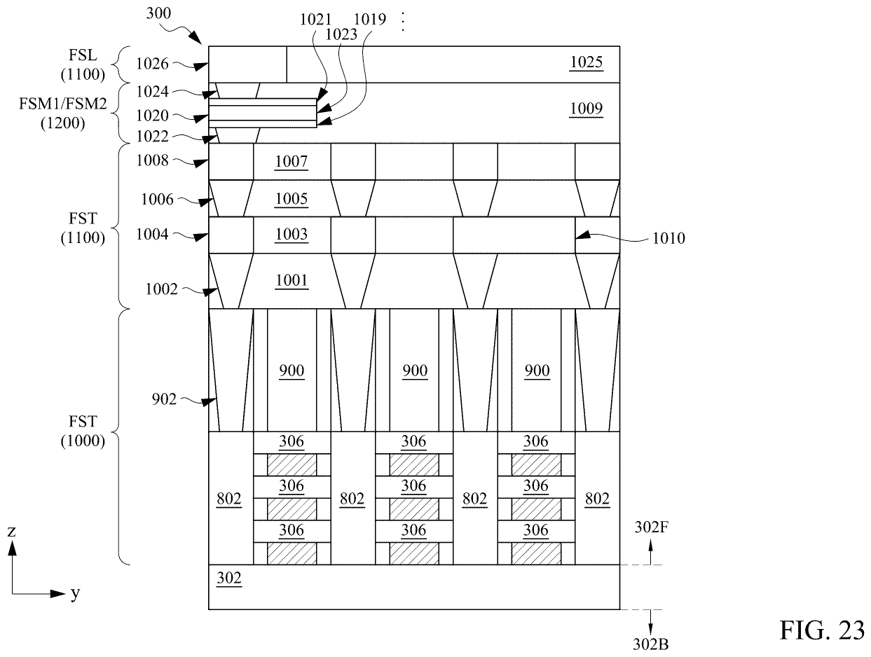

Referring to FIGS. 14 and 21, the dummy gate structures 600 are replaced with the active gate structures 900 at the sub-operation 264, in accordance with various embodiments. Replacing the dummy gate structures 600 includes first forming the ILD layer 806 the source/drain features 802. In some embodiments, the ILD layer 806 includes substantially the same composition as the ILD layer 117 described herein. The ILD layer 806 may be deposited by any suitable method, such as CVD, PECVD, FCVD, other suitable methods, or combinations thereof. Next, a planarization process, such as a CMP process, may be performed to achieve a level top surface for the ILD layer 806. The CMP may also remove the hard mask 604. After performing the planarization process, the top surface of the ILD layer 806 may be substantially level or coplanar with a top surface of the dummy gate structures 600.

Subsequently, still referring to FIG. 21, the dummy gate structures 600, the etch-stop layer 602, the patterned mask 402 (if still present), and the first semiconductor layers 304 are sequentially removed from the device 300 by one or more suitable etching processes, such as wet etching, dry etching, RIE, chemical oxide removal (COR), other suitable processes, or combinations thereof. After removing the dummy gate structures 600, the etch-stop layer 602, and the patterned mask 402 to form gate trenches, the top surface of each of the fin structures 400 (e.g., the top surface of the topmost semiconductor layers 306) is exposed. In addition to the top surface, sidewalls of each fin structure 400 may also be exposed. Next, the first semiconductor layers 304 are removed from each of the fin structures 400 to form openings by applying a selective etch (e.g., a hydrochloric acid (HCl)), while leaving the second semiconductor layers 306 substantially intact. After the removal of the first semiconductor layers 304, respective bottom surface and top surface of each of the second semiconductor layers 306 may be exposed in the openings.

Referring to FIGS. 14 and 21 still, the active gate structures 900 are formed in the gate trenches and the openings between the second semiconductor layers 306 at the sub-operation 266, in accordance with some embodiments. Each of the active gate structures 900 includes a substantially the same structure and composition as the active gate structure 16 described herein. In various embodiments, the active gate structures 900 may be formed in the exposed cavities (i.e., the gate trenches and openings between the second semiconductor layer 306) left by the dummy gate structures 600 and the first semiconductor layers 304. In some embodiments, the active gate structures 900 each include a top portion disposed above the second semiconductor layer 306 and a bottom portion interleaved with, or wrapping around each of, the second semiconductor layer 306.

The gate dielectric layer (not depicted separately) of the active gate structure 900 may be deposited using any suitable method such as thermal oxidation, chemical oxidation, CVD, ALD, PVD, other suitable methods, or combinations thereof. The gate metal may include a stack of multiple metal materials, such as the work function metals and the conductive fill layer, each of which may be formed by CVD, ALD, PVD, other suitable methods, or combinations thereof.

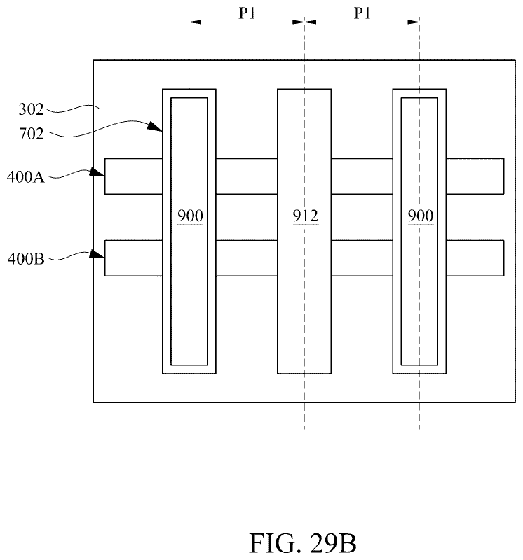

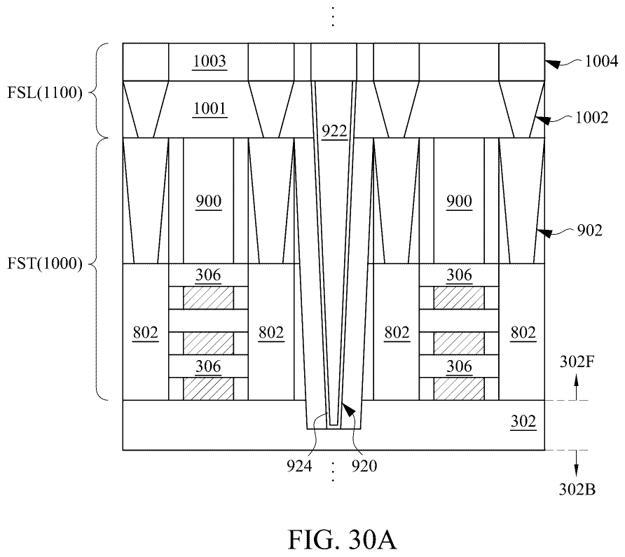

Subsequently, referring to FIG. 14, a subset (e.g., one or more) of the active gate structures 900 may be replaced with dielectric structure(s) (e.g., dielectric structure 912 in FIGS. 29A and 29B) at the sub-operation 268, where the dielectric structures are substantially similar to the dielectric structure 198 described herein. In some embodiments, the sub-operation 268 is optional and all active gate structure 900 remain in the device 300. The process of forming the dielectric structures 912 is described in reference to FIGS. 28A, 28B, 29A, and 29B.

In some embodiments, referring to FIGS. 28A and 28B, the subset of the active gate structures 900 are first removed by a series of photolithography and etching processes to form trenches 910, and, referring to FIGS. 29A and 29B, the trenches are then filled with one or more dielectric materials described herein with respect to the dielectric structure 198. In some embodiments, the trenches 910 extend vertically to below the frontside 302F and into the substrate 302. A planarization process (e.g., a CMP process) may be subsequently performed to planarize a top surface of the dielectric structure(s) with top surfaces of the remaining active gate structures 900. As described above, the dielectric structures 912 are configured to electrically isolate adjacent frontside devices (e.g., the FSMCs).

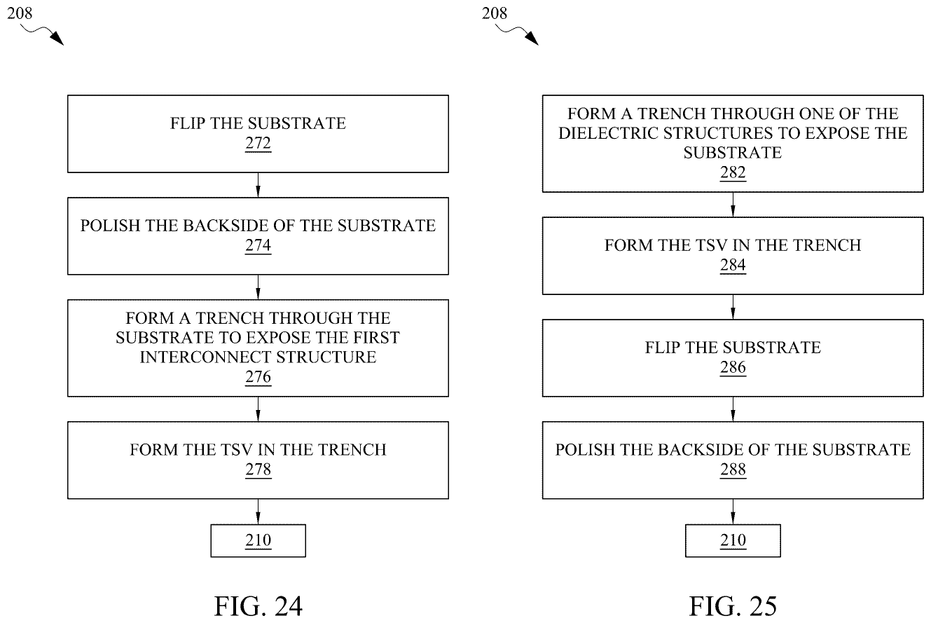

Referring to FIGS. 14 and 22, various contact features, such as source/drain contacts 902 and gate contacts (not depicted), are formed at sub-operation 270, in accordance with some embodiments. The source/drain contacts 902 are disposed in at least the ILD layer 806 and configured to electrically couple a corresponding source/drain feature 802 to the frontside interconnect structures 1100 (FSLs). The structure and composition of each source/drain contact 902 may be substantially the same as that of the source/drain contacts 18 described herein.

The source/drain contacts 902 may be formed by first patterning the ILD layer 806 disposed over the source/drain features 802, resulting in contact trenches, and depositing one or more conductive materials to form the source/drain contacts 902. A barrier layer (not depicted) may be formed in the trenches before depositing the conductive materials. Various layers of the source/drain contacts 902 may be formed by PVD, CVD, ALD, plating (e.g., electroplating, electroless plating, etc.), other suitable methods, or combinations thereof. In some embodiments, the source/drain contacts 902 each further include a silicide layer disposed over the corresponding source/drain features 802. A planarization process (e.g., a CMP process) may be subsequently performed to planarize a top surface of the source/drain contacts 902 with top surfaces of the active gate structures 900. Though not depicted, gate contacts may also be formed over the active gate structures 900 to electrically couple the active gate structures 900 to the FSLs 1100.

Upon performing the sub-operation 270 of FIG. 14, fabrication of the FSTs 1000 at the operation 202 of the method 200 (see FIG. 13) may be completed. The method 200 then proceeds to the operation 204 of forming the FSLs 1100 electrically coupled to the FSTs 1000.

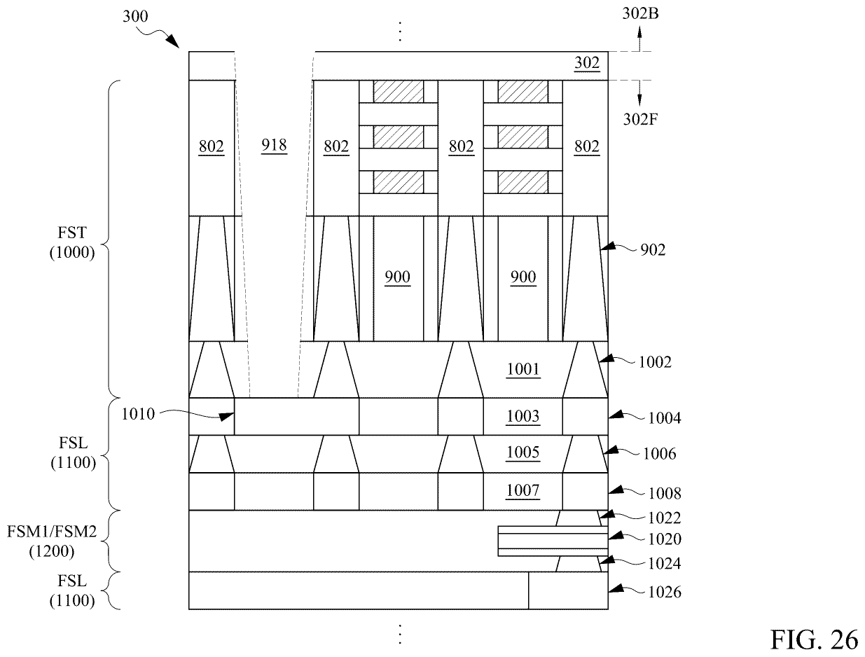

Referring to FIGS. 13 and 22, the FSLs 1100, which have structures substantially similar to those of the FSLs 15 described herein, include a number of conductive features (e.g., vias and metal lines) 1002, 1004, 1010 (in FIGS. 23), 1006, and 1008 embedded in corresponding IMD layers 1001, 1003, 1005, and 1007, in accordance with various embodiments. The conductive features 1002 and 1006 may be configured as vias similar to the vias V0 and V1, respectively, and the conductive features 1004 and 1008 may be configured as metal lines similar to the metal lines, M0 and M1, respectively. The structure and composition of the IMD layers 1001-1007 may be substantially the same as that of the IMD layers 120 and 122 described herein, which may be formed by any suitable method, such as CVD, PECVD, or FCVD. It is noted that the conductive features 1002, 1004, 1006, and 1008 and the IMD layers 1001, 1003, 1005, and 1007 are representative structures of the FSLs 1100 and not intended to limit the FSLs 1100 to any particular configuration.

The conductive features 1002-1008 (and any subsequently formed conductive features thereover) of the FSLs 1100 may be formed by at least some of the following processes. As a representative example, a recess may be formed in one of the IMDs through an etching process, such as dry etching, wet etching, RIE, other suitable etching processes, or combinations thereof. Next, the recess is filled with a conductive material, followed by a CMP process to remove any excess conductive material to planarize top surfaces of the conductive features 1002-1008 with the top surface of the corresponding IMD layers. In some examples, the conductive features 1002-1008 may be formed in the corresponding IMD layers 1001-1007 by a damascene process (e.g., a double damascene process, a single damascene process, etc.). The resulting conductive features embedded or encapsulated in their corresponding IMD layers are collectively referred to as metallization layers in the FSLs 1100.

As mentioned above, the conductive features 1002-1008 of the FSLs 1100 are formed to electrically couple the FSTs 1000 to other frontside and/or backside devices (e.g., the BSMs 1400, the BSLs 1300, etc.) through the TSVs 920. Although only the conductive features 1002-1008 are shown to connect to the source/drain features 802 of each FST 1000, it should be appreciated that at least one conductive feature of the FSLs 1100 can be connected to any of the active gate structures 900 of the FSTs 1000 while remaining within the scope of the present disclosure.

Referring to FIGS. 13 and 23, after forming portions (e.g., components proximal to the substrate 302) of the FSLs 1100, at least one FSM 1200 is formed to electrically couple to the FSLs 1100 along the vertical direction at operation 206, in accordance with some embodiments. In this regard, the resulting device 300 may have a structure similar to that depicted in FIGS. 10 and 12, for example. In some embodiments, the operation 206 is omitted.

In some embodiments, the FSM 1200 has a structure and composition substantially the same as that of the FSM 80 described herein. In some embodiments, the FSM 1200 is configured as a capacitor having an MIM structure, which includes a bottom electrode 1019 (alternatively referred to as a first metal layer), a top electrode 1021 (alternatively referred to as a second metal layer), and a dielectric layer 1023 (e.g., an insulating layer) interposed between the top and bottom electrodes.

In some embodiments, the FSM 1200 is formed compatibly with the conductive features 1002-1008 in the FSLs 1100. For example, each of the bottom electrode 1019, the dielectric layer 1023, and the top electrode 1021 may be formed by patterning IMD layer 1009 to form a trench (not depicted) and sequentially forming the bottom electrode 1019, the dielectric layer 1023, and the top electrode 1021 in the trench. After forming the FSM 1200, additional portions of the FSLs 1100, which may include conductive feature 1026 in an IMD layer 1025 and vias 1022 and 1024 in the IMD layer 1009, are formed in the device 300. The vias 1022 and 1024 electrically couple the bottom electrode 1019 and the top electrode 1021, respectively, to portions of the FSLs 1100.

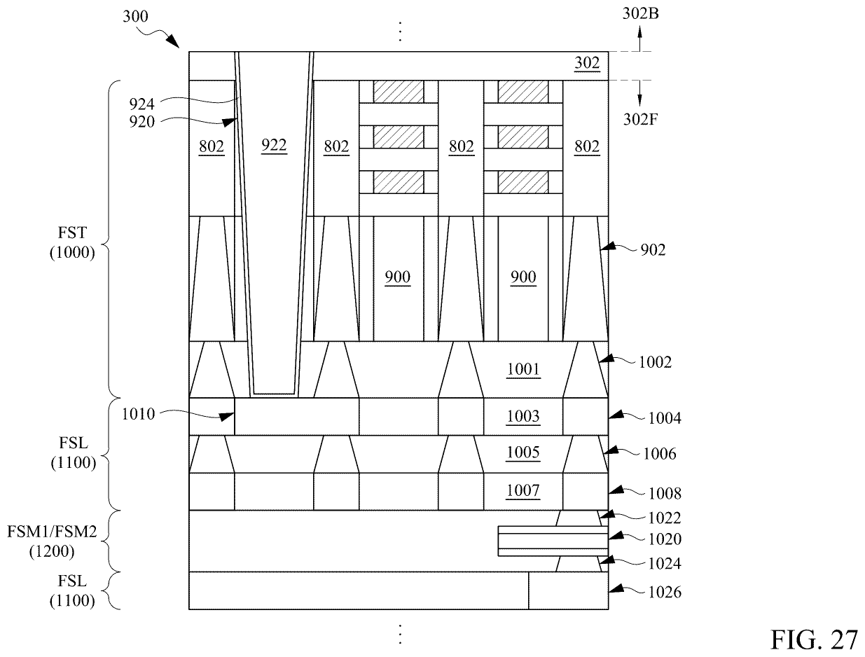

Referring to FIGS. 13 and 24-31, the TSVs 920 are formed in the device 300 to electrically couple the FSLs 1100 to subsequently formed BSLs 1300 at operation 208. In some embodiments, referring to FIGS. 24, 26, and 27 collectively, forming the TSVs 920 at the operation 208 may be implemented by sub-operations 272, 274, 276, and 278, for example.

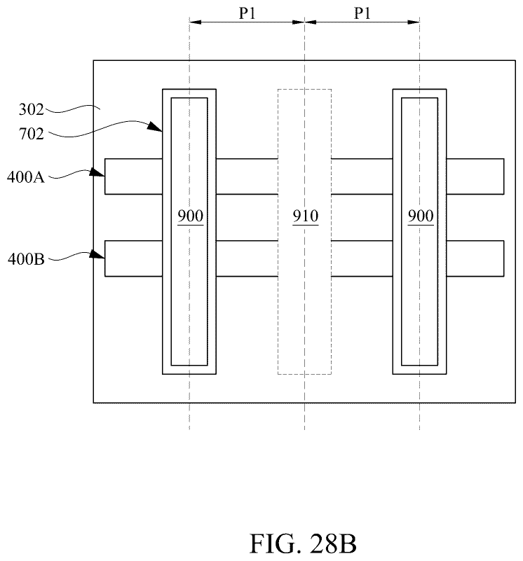

Referring to FIGS. 24 and 26, the substrate 302 is flipped and subject to further processing at the sub-operation 272, in accordance with some embodiments. For example, after forming a topmost metallization layer of the FSLs 1100 on the frontside 302F of the substrate 302, a carrier substrate may be attached to the topmost metallization layer, followed by flipping the substrate 302 on which a partially completed device 300 is formed. After flipping the substrate 302, a polishing process (e.g., a CMP process) is performed on the backside 302B at the sub-operation 274, in accordance with some embodiments.

Subsequently, still referring to FIGS. 24 and 26, a trench 918 that extends through the substrate 302 from the backside 302B to expose a portion of the FSLs 1100 is formed at the sub-operation 276, in accordance with some embodiments. In the depicted embodiment, the trench 918 exposes a metal line 1010 disposed in the IMD layer 1003. In some examples, the trench 918 may extend through a portion of one of the FSTs 1000. In some examples, the trench 918 may extend through a portion of the device 300 free of any frontside devices. The trench 918 may be formed by implementing a series of photolithography and etching processes to pattern the substrate 302. In some embodiments, one or more etching processes (e.g., dry etching, wet etching, RIE, etc.) and/or one or more etchants are used to form the trench 918.

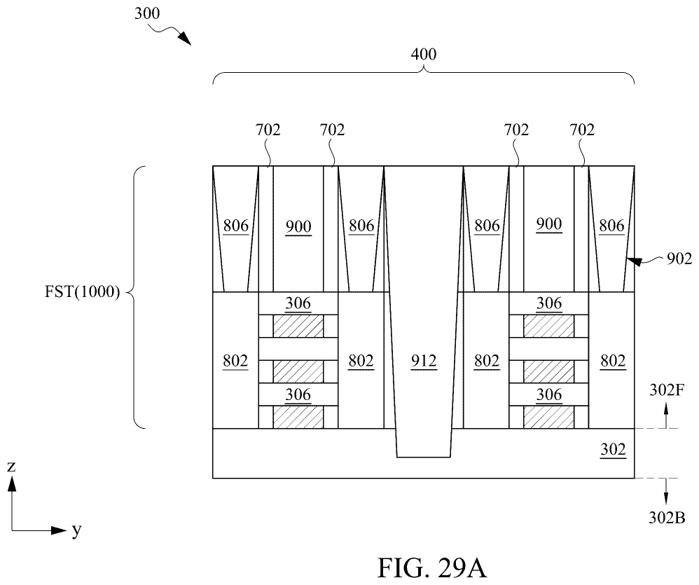

Referring to FIGS. 24 and 27, the TSV 920 is formed in the trench 918 at the sub-operation 278, in accordance with some embodiments. The TSV 920 may be formed by depositing a conductive fill layer 922 in the trench 928 by a process such as CVD, PVD, ALD, plating (e.g., electroplating, electroless plating, etc.), other suitable methods, or combinations thereof. Subsequently, a planarization process (e.g., a CMP process) may be performed to the conductive fill layer, rendering a top surface of the TSV 920 to be substantially planar with the backside 302B. In some embodiments, a barrier layer 924 is formed in the trench 918 before depositing the conductive fill layer 922. The barrier layer 924 may be conformally deposited by a process such as CVD, ALD, other suitable methods, or combinations thereof. The planarization process may also remove portions of the barrier layer 924 alongside the conductive fill layer 922.

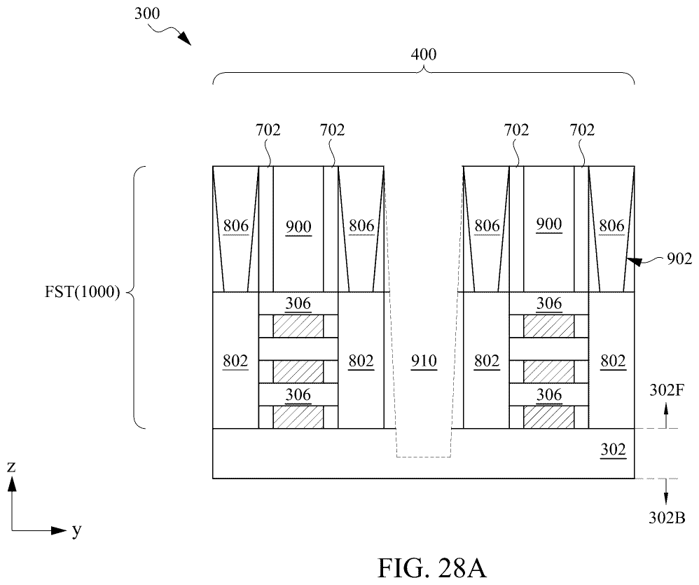

Alternatively, referring to FIGS. 25, 28A, 28B, 29A, 29B, 30A, and 30B collectively, forming the TSVs 920 at the operation 208 may be implemented by sub-operations 282, 284, 286, and 288, for example. FIGS. 28B, 29B, and 30B, corresponding to FIGS. 28A, 29A, and 30A, respectively, are top views of the device 300 on the frontside 302F depicting the process of forming and replacing the dielectric structures 912, in accordance with some embodiments.

Although only one of the dielectric structures 912 is shown to be replaced by the TSV 920, any suitable number of the dielectric structures 912 may be replaced based on various design requirements.

In the depicted embodiments, the TSV 920 replaces one of the dielectric structures 912 formed in place of the active gate structures 900 at the sub-operation 268 described herein. The process of forming the dielectric structures 912 is described above in reference to FIGS. 28A-29B. Referring to FIGS. 28B and 29B, the dielectric structures 912 extend lengthwise in parallel to the active gate structures 900. Furthermore, the dielectric structure 912 is separated from an adjacent active gate structure 900 at a pitch P1 that is substantially the same as the gate pitch between two adjacent active gate structures 900.

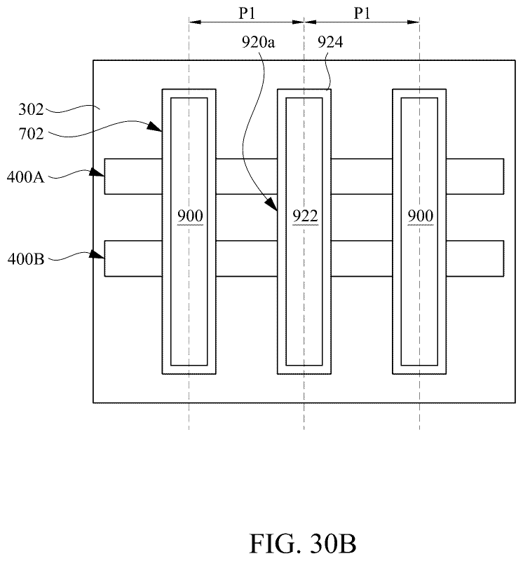

At the sub-operation 282, referring to FIGS. 30A and 30B, a trench (not depicted) is formed through one of the dielectric structures 912 to expose the substrate 302 by a series of photolithography and etching processes, for example. In some embodiments, the trench extends to below the frontside 302F and partially through (or into) the substrate 302. Subsequently, at the sub-operation 284, still referring to FIGS. 30A and 30B, the TSV 920 is formed in the trench. Various layers of the TSV 920 may be formed in the trench by one or more deposition processes including, for example, CVD, ALD, PVD, plating, other suitable processes, or combinations thereof. The resulting TSV 920 includes a bottom portion that extends into the substrate 302 and is partially embedded in the substrate 302 between the frontside 302F and the backside 302B. In some embodiments, some portions of the dielectric structure 912 may remain along sidewalls of the top portion 920a. In some embodiments, the sub-operations 282 and 284 are implemented concurrently with the formation of the FSLs 1100 during the operation 204.

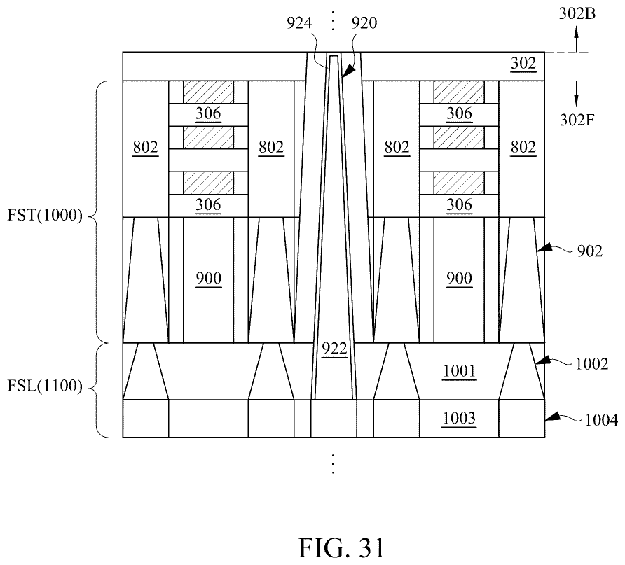

Referring to FIGS. 25 and 31, the substrate 302 is flipped at the sub-operation 286 in a manner similar to that of the sub-operation 272, in accordance with some embodiments.

Subsequently, at the sub-operation 288, the backside 302B of the substrate 302 is polished to expose the TSV 920 formed at the sub-operation 284, in accordance with some embodiments.

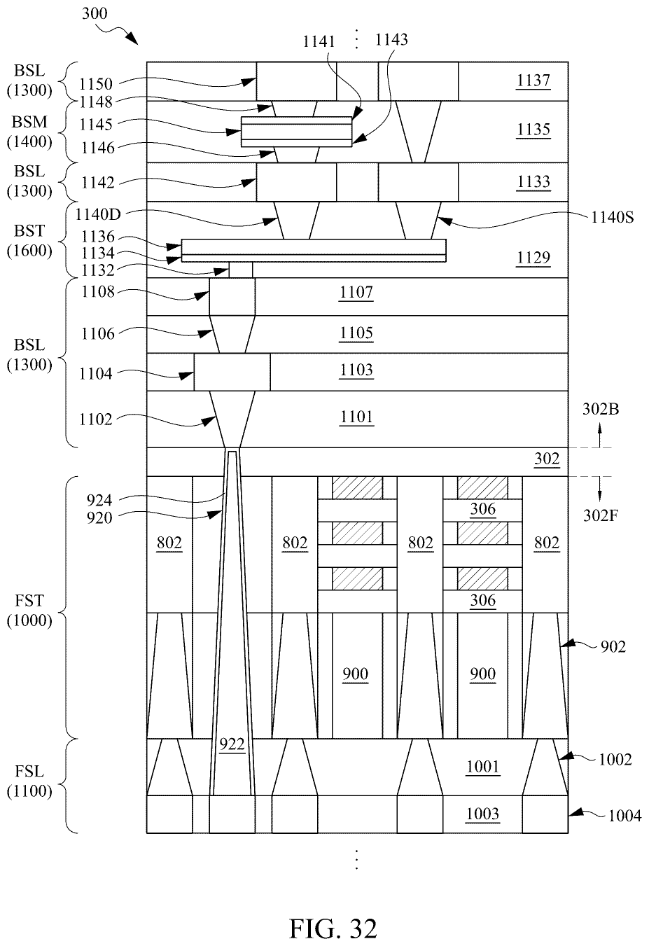

Referring to FIGS. 13 and 32, continuing with the method 200, the BSLs 1300 are formed on the backside 302B of the device 300 at operation 210, in accordance with some embodiments. The structure, composition, and fabrication method of the BSLs 1300 may be substantially similar to or the same as those of the FSLs 1100. For example, the BSLs 1300 include a plurality of representative IMD layers 1101, 1103, 1105, 1107, 1129, 1133, 1135, and 1137, as depicted in FIG. 32. The BSLs 1300 further include a plurality of representative conductive features, such as vias 1102 and 1106, and metal lines 1104, 1108, 1142, and 1150, embedded in the corresponding IMD layers.

Referring to FIGS. 13 and 32, the BST 1600 is formed on the backside 302B and electrically coupled to the BSLs 1300 at operation 212, in accordance with some embodiments. In some embodiments, the operation 212 is omitted.

The structure and composition of the BST 1600 may be substantially the same as those of the BST 60 described herein. For example, the BST 1600 includes a channel layer 1136 having a metal oxide semiconductor material. The BST 1600 includes source electrode 1140S and a drain electrode 1140D (collectively referred to as source/drain electrodes 1140) each extending from a respective end of the channel layer 1136 along the vertical direction. In some embodiments, at least one of the source/drain electrodes 1140 (e.g., the drain electrode 1140) is electrically coupled to the subsequently formed BSM 1400 (e.g., the top electrode thereof) through a portion of the BSLs 1300 (e.g., the metal line 1142). The BST 1600 further includes a gate dielectric layer 1134 overlaying the channel layer 1136 and a gate electrode 1132 disposed over the gate dielectric layer 1134. In some embodiments, the gate electrode 1132 is electrically coupled to portions of the BSLs 1300 (e.g., the metal lines 1108 and 1104 and the vias 1102 and 1106) disposed above (i.e., at a location proximal to the substrate 302) the BST 1600 and subsequently coupled to the FSLs 1100 through the TSV 920. The BST 1600 may be formed by sequentially depositing and patterning respective materials of the various features described herein.

Referring to FIGS. 13 and 32 still, the BSM 1400 is formed on the backside 302B at operation 214, in accordance with some embodiments. The structure, composition of the BSM 1400 may be substantially the same as those of the BSM 40 described herein. For example, the BSM 1400 is configured as a capacitor having an MIM structure formed in the IMD layer 1135. The BSM 1400 may include a bottom electrode 1141, a top electrode 1143, and a dielectric layer 145 sandwiched between the bottom electrode 1141 and the top electrode 1143. The BSM 1400 may be formed in the IMD layer 1135 in a manner similar to the FSM 1200 described herein.

If the BST 1600 is present, the BSM 1400 (e.g., the top electrode 1143 thereof) is electrically coupled to one of the source/drain electrodes 1140 (e.g. the drain electrode 1140D) of the BST 1600 through a via 1146, such that the BSM 1400 and the BST 1600 are coupled in series to form a backside memory cell (BSMC) having a 1T1C structure, similar to the BSMCs described above in reference to FIGS. 1 and 7. The BSM 1400 (e.g., the bottom electrode 1141 thereof) is further electrically coupled to portions of the BSLs 1300 (e.g., the conductive feature 1150 in the IMD layer 1137) below the BSM 1400 through a via 1148.

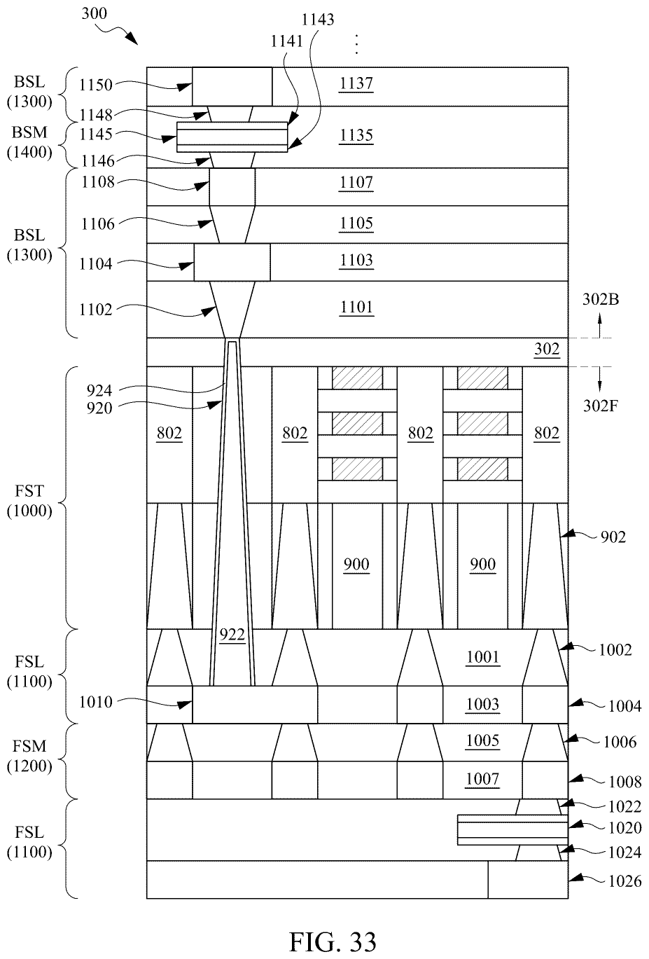

In some embodiments, referring to FIG. 33, the operation 212 is omitted such that the device 300 does not include any backside transistors (e.g., the BST 1600). In this regard, the BSM 1400 may be electrically coupled to one of the FSTs 1000 through portions of the BSLs 1300 (e.g., the metal lines 1108 and 1104 and the vias 1102 and 1106), the TSV 920, and a portions of the FSLs 1100 (e.g., the metal lines 1010 and any via in the IMD layer 1001 similar to the via 1002), which is further coupled to one of the source/drain features 802 of the FST 1000. Accordingly, the BSM 1400 and the FST 1000 are configured as a trans-substrate memory cell (TSMC) having a 1T1C structure, similar to the TSMCs described above in reference to FIGS. 8-10 and 12.

Accordingly, the present disclosure provides embodiments in which memory cells (of a memory portion) of a semiconductor device are fully (in the case of the BSMC in FIGS. 1,2, and 32) or partially (in the case of the TSMC in FIGS. 8-10, 12, and 33) formed on a backside of a substrate, thereby providing more space for additional memory cells of the memory portion and/or logic devices of a logic portion of the semiconductor device to be formed on a frontside of the substrate. As a result, various design rules to which the frontside features (e.g., the logic devices and the corresponding frontside interconnect structures) are subjected can be relaxed, allowing the frontside features to continue being scaled down without violating the design rules.

In one aspect of the present disclosure, a semiconductor device is disclosed. The semiconductor device includes a first transistor disposed on a first side of a substrate. The semiconductor device includes first interconnect structures disposed over the first transistor on the first side. The semiconductor device includes a memory element disposed on a second side of the substrate opposite to the first side, where the memory element includes at least a capacitor. The semiconductor device includes a via structure extending through the substrate and electrically coupling the memory element to the first interconnect structures.

In another aspect of the present disclosure, a semiconductor device is disclosed. The semiconductor device includes a first transistor disposed on a frontside of a substrate. The first transistor includes first semiconductor layers stacked along a vertical direction. The first transistor includes a source feature and a first drain feature respectively disposed adjacent to the first semiconductor layers. The first transistor includes a first gate structure interleaved with the first semiconductor layers. The semiconductor device includes a first interconnect conductive feature disposed over the semiconductor layers on the frontside, where the first interconnect conductive feature is electrically coupled to the first drain feature. The semiconductor device includes a first capacitor disposed on a backside of the substrate opposite to the frontside. The semiconductor device includes a second interconnect conductive feature electrically coupling the first capacitor to the first interconnect conductive feature along the vertical direction, where a portion of the second interconnect conductive feature extends through the substrate.

In yet another aspect of the present disclosure, a method for fabricating a semiconductor device is disclosed. The method includes forming a stack of semiconductor layers over a substrate. The method includes forming source/drain features respectively adjacent to the semiconductor layers. The method includes forming active gate structures each interleaved with the semiconductor layers. The method includes forming first interconnect structures over the first transistor on the frontside, where at least one of the source/drain features is electrically coupled to the first interconnect structures. The method includes forming a memory element on a backside of the substrate opposite to the frontside. The method includes forming a via structure electrically coupling the memory element to the first interconnect structure, where the via structure extends through the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a first transistor disposed on a first side of a substrate;
first interconnect structures disposed over the first transistor on the first side;
a memory element disposed on a second side of the substrate opposite to the first side, the memory element including at least a capacitor; and
a via structure extending through the substrate and electrically coupling the memory element to the first interconnect structures.

2. The semiconductor device of claim 1, wherein the capacitor includes a dielectric layer sandwiched between a bottom electrode and a top electrode.

3. The semiconductor device of claim 2, wherein the bottom electrode and the top electrode each include a ferromagnetic material.

4. The semiconductor device of claim 2, wherein the dielectric layer includes a ferroelectric material.

5. The semiconductor device of claim 1, wherein the memory element further includes a second transistor coupled to the capacitor in series.

6. The semiconductor device of claim 5, wherein the second transistor includes:
a channel layer including a metal oxide semiconductor material,
source/drain electrodes each extending from an end of the channel layer, one of the source/drain electrodes electrically coupled to the capacitor in series,
a gate dielectric layer overlaying the channel layer, and
a gate structure disposed over the gate dielectric layer, wherein the gate structure is electrically coupled to the memory element in series.

7. The semiconductor device of claim 1, wherein the first transistor comprises:
a plurality of nanostructures,
a source structure and a drain structure laterally coupled to one end of each of the plurality of nanostructures, the drain structure electrically coupled to the first interconnect structures, and
a gate structure wrapping around each of the plurality of nanostructures.

8. The semiconductor device of claim 7, wherein the memory element is electrically coupled to the drain structure through the via structure.

9. The semiconductor device of claim 1, further comprising second interconnect structures disposed on the second side and electrically coupling the memory element to the via structure.

10. The semiconductor device of claim 1, wherein the memory element is a first memory element, the semiconductor device further comprising:
a second transistor disposed on the first side adjacent to the first transistor;
third interconnect structures disposed over the second transistor on the first side; and
a second memory element disposed over the second transistor on the first side, the third interconnect structures electrically coupling a drain feature of the second transistor to the second memory element.

11. A memory device, comprising:
a first transistor disposed on a frontside of a substrate, the first transistor including:
first semiconductor layers stacked along a vertical direction,
a first source feature and a first drain feature respectively disposed adjacent to the first semiconductor layers, and
a first gate structure interleaved with the first semiconductor layers;
a first interconnect conductive feature disposed over the first semiconductor layers on the frontside, the first interconnect conductive feature being electrically coupled to the first drain feature;
a first capacitor disposed on a backside of the substrate opposite to the frontside; and
a second interconnect conductive feature electrically coupling the first capacitor to the first interconnect conductive feature along the vertical direction, a portion of the second interconnect conductive feature extending through the substrate.

12. The memory device of claim 11, wherein the first interconnect conductive feature electrically couples the second interconnect conductive feature to the first drain feature.

13. The memory device of claim 11, further comprising a third interconnect conductive feature electrically coupling the first capacitor to the second interconnect conductive feature.

14. The memory device of claim 11, further comprising:
a second transistor, including:
second semiconductor layers disposed on the frontside and stacked along the vertical direction,
a second drain feature disposed adjacent to the second semiconductor layers, and
a second gate structure interleaved with the second semiconductor layers, wherein the first source feature is a common source feature shared between the first transistor and the second transistor;
a third interconnect structure disposed on the frontside and electrically coupled to the second drain feature; and
a second capacitor disposed on the frontside and electrically coupled to the third interconnect structure.

15. The memory device of claim 14, wherein the second interconnect conductive feature extends parallel to the first gate structure and the second gate structure in a top view of the frontside, and wherein a first pitch between the second interconnect conductive feature and the first gate structure is the same as a second pitch between the first gate structure and the second gate structure.

16. The memory device of claim 11, wherein the first capacitor is configured as a component of a dynamic random access memory (DRAM) cell, a magnetoresistive random access memory (MRAM) cell, a resistive random access memory (ReRAM) cell, or a ferroelectric random-access memory (FeRAM) cell.

17. A method for fabricating a memory device, comprising:
forming a stack of semiconductor layers on a frontside of a substrate;
forming source/drain features respectively adjacent to the stack of semiconductor layers;
forming active gate structures each interleaved with the stack of semiconductor layers and interposed between the source/drain features, resulting in a first transistor;
forming first interconnect structures over the first transistor on the frontside, at least one of the source/drain features being electrically coupled to the first interconnect structures;
forming a memory element on a backside of the substrate opposite to the frontside; and
forming a via structure electrically coupling the memory element to the first interconnect structures, the via structure extending through the substrate.

18. The method of claim 17, further comprising forming second interconnect structures on the backside, the second interconnect structures electrically coupling the via structure to the memory element.

19. The method of claim 17, wherein forming the via structure includes:
replacing at least one of the active gate structures with a dielectric structure,
forming a trench in the dielectric structure on the frontside, the trench extending partially through the substrate,
forming the via structure in the trench, the via structure extending parallel to the active gate structures in a top view of the frontside,
flipping the substrate, and
polishing the backside to expose the via structure before forming the memory element.

20. The method of claim 17, wherein forming the via structure includes:
flipping the substrate,
polishing the backside,
forming a trench on the backside, the trench extending through the substrate to expose a portion of the first interconnect structures, and
forming the via structure in the trench.
